(19) United States
(12) Patent Application Publication
(10) Pub. No.: US 2021/0020766 A1
(43) Pub. Date: Jan. 21, 2021

(54) CHARGE TRANSFER LOGIC (CTL) USING COMPLEMENTARY CURRENT FIELD EFFECT TRANSISTOR DEVICES (CiFET) AND / OR COMPLEMENTARY SWITCHED CURRENT FIELD EFFECT TRANSISTOR DEVICES (CsiFET)

(71) Applicant: Circuit Seed, LLC, Newport Beach, CA (US)

(72) Inventors: Susan Marya Schober, Newport Beach, CA (US); Robert C. Schober, Huntington Beach, CA (US); Timothy Howard Richards, Costa Mesa, CA (US); Terrence R. Hudrlik, Blaine, MN (US); Aaron Curry, Los Angeles, CA (US)

(21) Appl. No.: 16/982,029

(22) PCT Filed: Mar. 20, 2019
(86) PCT No.: PCT/US2019/023094

§ 371 Date: Sep. 17, 2020

Related U.S. Application Data
(60) Provisional application No. 62/645,533, filed on Mar. 20, 2018.

(51) Int. Cl. H01L 29/768; H01L 27/092

(52) U.S. Cl. CPC H01L 29/768; H01L 27/092

(57) ABSTRACT

The present invention relates to novel inventive compound device structures, enabling charged-based logic gates. In particular, a switched p-channel and/or n-channel current field effect transistor, a solid state device based on a complimentary pair of a switched p-channel and n-channel current field effect transistors, and/or a solid state device based on a complimentary pair of a p-channel and n-channel current field effect transistors are used for constructing such logic gates. The switched current field effect transistor comprising a source and a drain, wherein the source and drain defines a channel, a diffusion that divides the channel into a source channel segment between the source and the diffusion and a drain channel segment between the drain and the diffusion, a source channel gate that is coupled to the source channel, and a drain channel gate that coupled to the drain channel. These novel device structures provide various improvements over the conventional devices.

### CROSS-REFERENCE TO RELATED APPLICATIONS

This application claims priority to U.S. Provisional Application No. 62/645,533 filed on Mar. 20, 2018, entitled “CHARGE TRANSFER LOGIC (CTL) USING A COMPLEMENTARY CURRENT FIELD EFFECT TRANSISTOR DEVICE (CiFET)”, the contents of which are incorporated herein by reference in its entirety.

### BACKGROUND OF THE INVENTION

### Field of the Invention

The present invention relates to the development of a new charge transfer logic (CTL) based on CiFETs and/or CsiFETs to develop the logic circuits that include OR, AND, NOR, NAND and various flip flops. These circuits form the logic functionality of any physical digital device. The CiFET/CsiFET as a logic device uniquely serves both the CTL stream and provides voltage logic levels as well, if desired. This new logic capability is developed, among other things, from the CiFET devices disclosed in PCT international applications PCT/US2015/042696 and PCT/US2016/044800, the contents of which are incorporated herein by reference in its entirety.

### Description of Related Art

The logic circuits presented are made possible as a result of the CiFETs unique capabilities including a transresistance transform that translates current into voltage. This ability to steer and manipulate very small currents using CiFET devices developed from standard CMOS digital process nodes is the basis of this logic. CiFET logic interfaces readily with the hosting CMOS process and CMOS circuits allowing a seamless transition between the capabilities and designs of existent CMOS designs and the incorporation of CTL into their designs.

The problem of system integration from the front-end analog signals to the digitization of same to the computer or DSP processing of same to the final output of that processed data for other systems use requires at present several discrete IC chips bonded together on a hybrid ceramic board to achieve such integrated system capability. CiFET logic provides a path between the analog world through its analog capability to its very fast A/D converters disclosed in PCT international application PCT/US2016/067529, the contents of which are incorporated herein by reference in its entirety, to the CiFET logic that can implement or be integrated into the complex systems that include microcomputers and DSP elements. As the CiFET process embraces all of the steps in this system chain the entire system could be designed as a single system on a chip with CiFET analog as the input and CiFET digital as the output, without the need analog IC process extensions.

Many design advantages are incurred using CiFETs in a design; those include wide Vdd supply values ultra-wide temperature operating range and extremely high invertor gain making CiFET charge steering logic capable of very high-speed operation as current based logic does not engage the parasitic capacitances.

### Prior Art

### Faster Computational Throughput is Stopped by the Production and Removal of Heat.

Presently increasing digital information processing capability has been stopped by a power dissipation wall. It is not practical to increase processor clocking rate beyond mid-3 Gz as it is not possible to shed the heat generated fast enough.

While heat dissipation is important to the single chip it becomes the critical when large numbers of processors are used in a system such as a server farm. It is estimated that 10% of all the power generated in the US, is used to power computers and IT equipment and this grows by 7% per year according to the SMART 2020 report. The fastest growing sector is the cell 4G links and soon 5G links. The cost of transmitting a megabyte of data over these links is a couple kilojoules of energy, as wireless use grows this sector will experience the greatest immediate worldwide growth. The push into 5G is needed for the IOT and even self-driving cars will demand it. This will dramatically increase the growth rate for high speed data transmission. A paradigm shift is needed to break through the power barriers presently limiting computational throughput.

As the demands on both analog and digital circuitry increases and evolves there exists an ever-present push toward merging the world of analog interface information into the world of digital processing. An IC process node merger between high-quality analog, unique digital capabilities and a seamless ability to merge into the ever-shrinking CMOS process nodes will allow seamless high-level system integrations. Such a merger would enable true one chip system solutions to many sensor-based systems. This capability would require compatibility at the device level of both the analog and digital design elements. Parasitic distributed capacitance directly impacts a digital circuit's performance and adds to the chip circuit heat. A logic family that largely bypasses this limitation will benefit many digital designs problems simultaneously. As single nanometer integrated circuit designs are pushed, it is realized that the achieved gain of these devices collapse as their modulated drain current is shorted out by the ever-smaller source to drain resistance. This is one of the reasons why analog design nodes lag digital process nodes by several generations.

Newer digital designs have but one process node complimentary pair optimized transistors for use in their designs. Process nodes at nanometer scales are very inflexible.

The differences in digital and analog process node requirements keep complex analog designs and complex digital designs on separate chips using separate process nodes to be interconnected when placed on the same unifying ceramic substrate board. Such off-chip interconnects provide a ready access point for noise as well as requiring large buffers to drive the external pins. Speed considerations differ dramatically for internal and external nodes. In addition, off chip signals decrease the reliability of the overall design.

Operation of CMOS voltage swing logic circuits begin to fail below a supply voltage of about 800 mv. Many computational sensing systems would benefit by lower operational voltages, wider operational temperature range and a high bandwidth.

Parallel processing is often talked about, there and many uses for such a logic streaming capability that could dramatically reduce the real estate and the power needed to produce such a functioning capability. The ability to interconnect dynamically or reconfigure its logic if needed to reprogram itself brings the capability of a dynamic 3D structure. This changing structure could in a sense envelope the information data streams and produce a production line type signal processing structure, as real interconnections are made and re-made to suit the immediate data processing needs. These interconnect structures if they could be instantly extracted and implemented would be that dynamic machine for that moment. However, if interconnections and such a dynamic structure could be built it would offer some new unique capabilities to the science of DSP.

In conventional logic the answer is (0,1) with much work are the logic decisions. In AI logic runs on probabilities at every level of operation. As you cannot know the answer of among the almost infinite choices, some 10\hat{ }350 such choices in the game GO, AI logic can only hope to give you its best guess. This probabilistic need even demands instead of a hard comparator a sigmodal shaped threshold dynamic. This threshold comparator needs to be dynamically programmable to allow for the changes in weighting decisions.

Additionally, while binary logic systems have only 2 states (0,1), there is a growing need for the ability to process graded logic levels and to be able to pull that logic binary signal capability from low level analog processes and all on small real estate in a complete SOC implementation. Shrinking the IC process nodes for smaller planar interconnect areas was to produce smaller interconnect node capacitances, however, as the feature size shrinks, the modulated drain current shunts the shortened channel regions. As the inter-element spacing decreases the nearby parasitics increase at times faster than the (gm) of the device increases due to its smaller size. These changes in parasitics also impact the chips power consumption. Voltage mode FinFETs and silicon on insulator (SOI) physical layout helped the semiconductor layer control capacitance parasitics and provided the higher drive capability so node voltages could switch faster, and signal levels would stay above noise margins. These improvements have driven designs to use multiple concurrent cores running with mid-3.0 GHz clock speeds as the practical tradeoff in the speed, throughput, heat generation and manufacturability when considering maximizing digital information processing.

In present designs in order to minimize the ½CV² power losses to the parasitic capacitances at high frequency the node voltage swing that defines “0” & “1” has been reduced to the noise floor's reliability limit.

One of the fastest logic available is emitter coupled logic (ECL), which is a voltage-based logic. It relies on differential input sensing and differential output logic drive for its speed.

The ½CV² power loss often radiates and degrades the local noise floor. The intra and interconnects are the main source of higher frequency power consumption as well as the I²R conductivity-based losses of the semiconductor layer and interconnect. Smaller process dimensions produce closer metal interconnect structures which cause the parasitics to increase in a relative sense as the dimensions decrease. Longitudinal as well as surface area related impedance impacts must be considered as crosstalk and capacitive loss pathways use any capacitance coupling as a media to degrade noise levels in voltage-based systems. As dimensions shrink resistance of interconnects go up and often need to be compensated by increasing cross-section of interconnections leading to thicker metal to achieve switching goals. Smaller IC process node transistors are faster, however, the greater sidewall, longitudinal, interconnect capacitance increase with process node shrinkage which in turn increases ½CV² losses effectively cancelling out many of the hoped-for speed and heat advantages of the smaller process node. With a voltage-based logic family higher frequency clocking means higher power consumption. As the process node shrinks, the magnitude of the parasitic capacitances often actually increases with the net result that feature size and power consumption do not linearly track. This uncertainty decreases the predictability of one's design. Fast logic voltage signals generate sizable supply current spikes from charging the interconnect capacitances. Ground noise added to the signal lines or power lines decreases the logic levels noise margin. With current logic levels current loops are established which inherently shuns current noise injection. Additionally, if the current level is turned into a local logic voltage level that voltage signal is locally referenced at the receiver again shunning the introduction of some noise sources.

### SUMMARY OF THE INVENTION

Charge transfer logic (CTL) is counter-intuitive in that mature CMOS logic is excellent for relatively static logic in that only leakage power is consumed most of the time, but C*V² power is its limitation. Going fast burns power in CMOS, but in this CiFET CTL or CsiFET CTL, power increase is almost non-existent along with its excessive speed. This is because transferring charge from the logic signal source to the logic receiver's low impedance input does not significantly change the voltage on the interconnect wires. Also, the wire count is not the number of logic transmitted signals; but the count of receivers. Gates are formed by just wire-OR'ing logic transmitted charge/current, which is on the order of a few nano-amps terminated into each receiver.”

According to one aspect of the present invention, it provides a field effect transistor comprising: a source and a drain, wherein the source and drain define a channel; a diffusion that divides the channel into a source channel segment between the source and the diffusion and a drain channel segment between the drain and the diffusion; a source channel gate that is coupled to the source channel segment; and a drain channel gate that coupled to the drain channel segment. The diffusion may be a current input or current output node. The diffusion may be a current sink or current source node. Furthermore, the source channel gate is coupled to a common mode voltage, the source is coupled to a power source, and the drain channel gate is configured to receive a logic voltage input for providing a logic current output at the drain.

According to another aspect of the present invention, it provides a solid-state device, comprising: a complementary pair of first and second field effect transistors as recited hereinabove, wherein, the drain of the first complementary field effect transistor and the drain of the second complementary field effect transistor are coupled together to form a drain port. Furthermore, the source channel gate and the drain channel gate of the first complementary field effect transistor and the source channel gate and the drain channel gate of the second complementary field effect transistor are coupled together to a common mode voltage. The solid-state device is arranged to receive a logic current input at the diffusion of the first complementary field effect transistor and/or the second diffusion of the second complementary field effect transistor to generate a logic voltage output at the drain port.

According to yet another aspect of the present invention, it provides a logic current to logic voltage converter, comprising: a complementary pair of first and second field effect transistors, each comprising a source and a drain, wherein the source and drain of the first transistor define a first channel and the source and drain of the second transistor define a second channel; a first diffusion (first iPort) that divides the first channel into a first source channel segment between the source and the first iPort, and a first drain channel segment between the drain and the first iPort; a second diffusion (second iPort) that divides the second channel into a second source channel segment between the source and the second iPort and a second drain channel segment between the second iPort and the drain; a gate coupled to the first source channel segment, the first drain channel segment, the second source channel segment, and the second drain channel segment; and wherein the drain of the first complementary field effect transistor and the drain of the second complementary field effect transistor are coupled together to form a drain port; wherein the gate is coupled to a common mode voltage, the sources of the first and second complementary field effect transistors are coupled to power supply; and wherein the logic current to logic voltage converter is arranged to receive a logic current input at the first iPort or the second iPort for generating a logic voltage output at the drain port.

A charge transfer logic module having two or more logic input and a logic output, comprising: a solid-state device as recited hereinabove, wherein the sources of the first and second complementary field effect transistors are coupled to a power supply; for each of two or more logic input voltage, a logic voltage to logic current converter for converting said each logic input voltage into a logic current; wherein the diffusion of the first or the second complementary field effect transistor is configured to receive said logic current from the converter; and wherein the drain port of the solid-state device is configured to output the logic voltage output. Furthermore, the voltage to current converter comprises a field effect transistor, comprising: a source and a drain, wherein the source and drain defines a channel; a diffusion that divides the channel into a source channel segment between the source and the diffusion and a drain channel segment between the drain and the diffusion; a source channel gate that is coupled to the source channel segment; and a drain channel gate that coupled to the drain channel segment; wherein the source is coupled with a power supply, the source channel gate is coupled with a common mode voltage, the drain channel gate is configured to receive one of the two or more logic voltage input for generating a logic current output from the drain.

According to further aspect of the present invention, it provides a logic voltage to logic current converter, comprising: a field effect transistor, comprising: a source and a drain, wherein the source and drain defines a channel; a diffusion that divides the channel into a source channel segment between the source and the diffusion and a drain channel segment between the drain and the diffusion; a source channel gate that is coupled to the source channel segment; and a drain channel gate that coupled to the drain channel segment; wherein the source is coupled with a power supply, the source channel gate is coupled with a common mode voltage, the drain channel gate is configured to receive a logic voltage input for generating a logic current output from the drain.

According to yet further aspect of the present invention, it provides a data bus structure, comprising: a bus; a bus transmitter comprising a field effect transistor, comprising: a source and a drain, wherein the source and drain defines a channel; a diffusion that divides the channel into a source channel segment between the source and the diffusion and a drain channel segment between the drain and the diffusion; a source channel gate that is coupled to the source channel segment; and a drain channel gate that coupled to the drain channel segment; wherein the source is coupled with a power supply, the source channel gate is coupled with a common mode voltage, the drain channel gate is configured to receive a logic voltage input for generating a logic current output from the drain to the bus; and a bus receiver comprising a complementary pair of first and second field effect transistors, each comprising: a source and a drain, wherein the source and drain of the first transistor define a first channel and the source and drain of the second transistor define a second channel; a first diffusion (first iPort) that divides the first channel into a first source channel segment between the source and the first iPort, and a first drain channel segment between the drain and the first iPort; a second diffusion (second iPort) that divides the second channel into a second source channel segment between the source and the second iPort and a second drain channel segment between the second iPort and the drain; a gate coupled to the first source channel segment, the first drain channel segment, the second source channel segment, and the second drain channel segment; and wherein the drain of the first complementary field effect transistor and the drain of the second complementary field effect transistor are coupled together to form a drain port;

wherein the gate is coupled to a common mode voltage, the sources of the first and second complementary field effect transistors are coupled to power supply; and wherein the bus receiver is arranged to receive the logic current from the bus at the first iPort or the second iPort for generating a logic voltage output at the drain port.

According to yet further aspect of the present invention, it provides a charge-based clock-tree, comprising: a bus structure as recited hereinabove; wherein the drain channel gate of the bus transmitter is configured to receive a logic voltage clock signal for conversion into a logic current clock signal to be transmitted on the bus.

### BRIEF DESCRIPTION OF THE FIGURES

The present invention will now be described in more detail with reference to the accompanying drawings, in which:

FIG. 1a illustrates a schematic diagram of a basic complementary switched current field effect transistor (CsiFET) biased Vgs stack;

FIG. 1b illustrates a schematic diagram of a basic complementary current field effect transistor (CiFET) signal references with Vin;

FIG. 1c illustrates a schematic diagram of a CiFET common mode voltage Vcm generator;

FIG. 1d illustrates a three-dimensional perspective view of a CiFET device;

FIG. 1e is a visualization of channel current flow on a basic CiFET;

FIG. 1f is an analogical conceptual diagram of energy flow within a basic CiFET/CsiFET;

FIG. 2 shows a graph showing the biased operational performances of a CiFET/CsiFET;

FIG. 3a illustrates a schematic diagram of a switched p-channel current field effect transistor iFET (PsiFET) voltage-LOGIC to current-LOGIC conversion;

FIG. 3b illustrates a schematic diagram of a switched n-channel current field effect transistor (NsiFET) voltage-LOGIC to current-LOGIC conversion;

FIG. 3c illustrates a symbol diagram of a switched p-channel current field effect transistor (PsiFET) current source;

FIG. 3d illustrates a symbol diagram of a switched n-channel current field effect transistor (NsiFET) current source;

FIGS. 4a and 4b illustrate a logic current-to-voltage convertor based on a CsiFET;

FIGS. 4c and 4d illustrate another logic current-to-voltage convertor based on a CsiFET;

FIG. 5a shows a voltage-based data transmission coupled with the CiFET latched voltage receiver;

FIG. 5b shows a current based data transmission coupled with the CiFET/CsiFET latched current receiver;

FIG. 6a illustrates a schematic diagram of a wire-OR circuit with voltage-level and current-level LOGIC inputs/output;

FIG. 6b illustrates a schematic diagram of a wire-AND gate having inverted inputs & inverted output employing either/both voltage/current-mode LOGIC signals;

FIG. 7a shows a CMOS LOGIC schematic diagram for 4-input NOR logic;

FIG. 7b shows a schematic diagram of a 4-input CiFET iPort wired-OR logic;

FIG. 8a illustrates the prior art silicon layout and relating physical size of a CMOS Inverter;

FIG. 8b illustrates the prior art silicon layout and relating physical size of a CMOS 2-Input OR gate;

FIG. 8c illustrates the CiFET device and silicon layout plan relating physical size in planar CMOS;

FIG. 8d illustrates the CiFET device and silicon layout plan relating physical size in FinFET technology;

FIG. 8e shows the CMOS 4-input NOR silicon physical layout plan for size comparison;

FIG. 9a illustrates a schematic diagram of a CTL voltage-holding-LATCH with wire-AND logic-voltage and logic-current logic input/output interfaces according to the present invention;

FIG. 9b illustrates a schematic diagram of a CTL voltage-holding-LATCH with wire-OR logic-voltage and logic-current logic input/output interfaces according to the present invention;

FIG. 9c shows plots that demonstrate the voltage-holding-LATCH −170° C., −55° C., 25° C., 125° C., & 275° C. example-waveforms;

FIG. 10a illustrates a schematic diagram of a CTL full-current-mode wire-AND high-fan-inn LATCH with I/O options for high-bus-traffic & high-speed;

FIG. 10b illustrates a schematic diagram of a CTL full-current-mode wire-OR high-fan-inn LATCH with I/O options for high-bus-traffic & high-speed;

FIG. 10c shows plots that demonstrate the current-steered LATCH −170, −55, 25, 125, & 275° C. example-waveforms;

FIG. 11 illustrates a schematic diagram of a data processing bus read/write amp (full current-mode ALU is also implementable for high-speed);

FIG. 12 illustrates a schematic diagram of a charge-based clock-tree, which provides equal timing to all receivers by uniform current transfer providing simple timing closure at max speed and area-density;

FIG. 13 illustrates a schematic diagram of a charge-based edge to pulse generator;

FIGS. 14a to 14c illustrate symbol and schematic diagrams of a current input operated Schmitt trigger;

FIG. 15a is a schematic diagram of a common voltage generator;

FIG. 15b illustrates a schematic diagram of a CTL stacked processing array; and

FIG. 16 shows a schematic diagram of a charge pump circuit based on CsiFET.

### DETAILED DESCRIPTION OF THE INVENTION

Charge transfer logic (or CTL) is a compact system where one or more logically defined current or charge signals are transmitted on a single wire from one or more logic signal sources to a logic receiver in the form of a current or pulse of charge. The current/charge logic signals are defined as positive for an inward current and negative for an outward current, both of which have magnitudes defined by convention, the (“0”,“1”) levels. In addition, a NO-Change or NO-current state exists which draws no power. In graded logic it often necessary to represent a logic decision with a non-binary output, the CTL can provide such a graded output as well. The graded multi-logic level capability of the CiFET both on the receive and transmit end of logic operations would enable non-binary logic circuits. In such circuits current levels could, for example, be graded into 4 current levels; as such since there are 4 current levels, each level would encode 2 binary bits. This increased signal information would in effect double the bus speed. While these types of non-binary circuits have been developed before the CiFETs unique mix of analog functional capability, its digital logic capabilities and its ability to interface seamlessly to its hosting CMOS family bring a new level system integration capability. A capability that scales and offers operating temperature ranges exceeding −170 to 275 degrees C.

CTL can also be triggered, such as in a flip flop structure, to flip states as the set or reset lines receive a pulse of current over a specific period of time, with the advantage that the latch needs no holding current once the latch has switched states. The CTL can be operated as a voltage triggered logic or a current steering logic. In the current steering logic mode, the logic speed can be made to operate quite fast as the parasitic capacitances are essentially bypassed as the node voltages remain essentially constant.

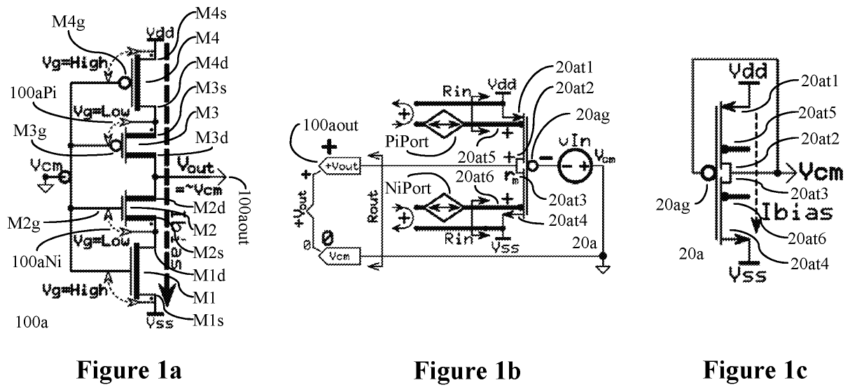

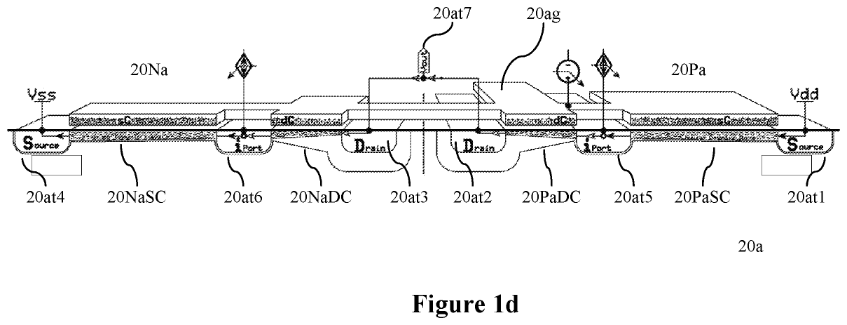

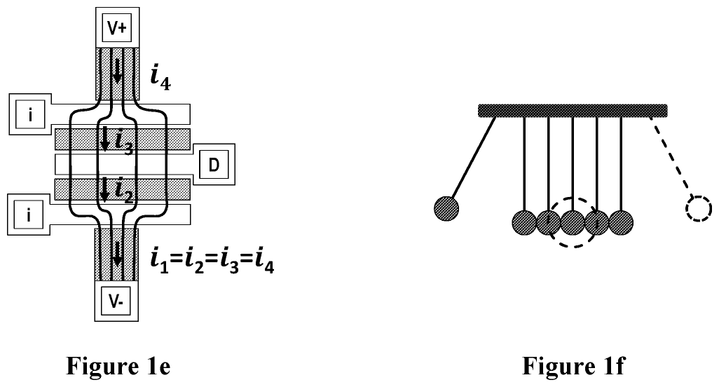

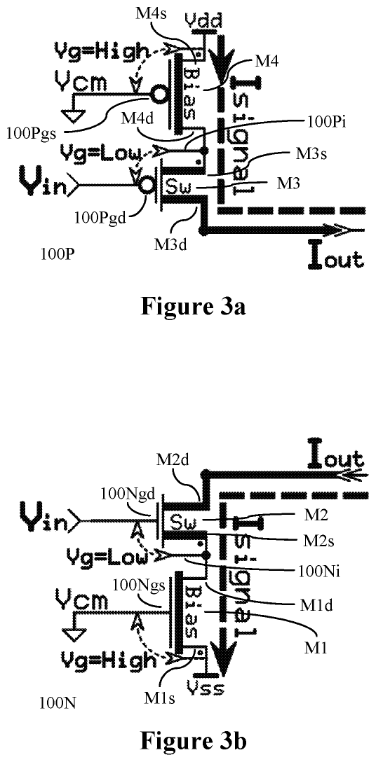

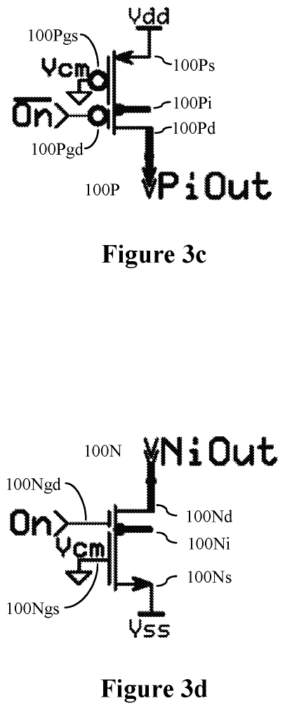

FIG. 1d depicts a cross-sectional view of a CiFET 20a, the details can be found in PCT international application Nos. PCT/US2015/042696 and PCT/US2016/044800, the contents of which are incorporated herein by reference in its entirety. CiFET 20a includes a complementary pair of iFETs, namely p-type iFET (PiFET) 20Pa and n-type iFET (NiFET) 20Na. Drains 20at2 and 20at3 are coupled together to form a drain port 20at7. Sources 20at1 and 20at4 are coupled to a power source (Vss and Vdd, respectively). When used for digital purposes operational diffusion points 20at5 and 20at6 are adjusted such that source channel segment 20PaSC of the p-type iFET (PiFET) 20Pa (channel segment between the source 20at4 and PiPort 20at6) and source channel segment 20NaSC of the n-type iFET (NiFET) 20Na (channel segment between the source 20at1 and the NiPort 20at5) are operationally supersaturated where the charge density and the charge channel depth is increased and the drain channels 20at2 and 20at3 of PiFET 20Pa and NiFET 20Na are saturated, but below pinch off. In FIG. 1d, all the channel gates (source and drain channel segments of PiFET and NiFET, 20PaSc, 20PaDc, 20NaSc and 20NaDc) are arranged to be connected to Vcm. In some types of circuits using CsiFET, the individual gates may connect differently as shown in FIGS. 3a and 3b, where the siFET current logic connections are arranged such that the source channel gate is connected to Vcm and the drain channel gate may be used for logic signal input.

As the channel segments are saturated energy movement through these channel segments consist of small charge displacements that respond very quickly to the modulated demands. This type of small displacement energy movement is depicted by FIG. 1f, which uses a Newton's cradle to demonstrate how input energy to output energy flow occurs with very little displacement of the intervening displaceable carriers.

In FIG. 1e, the channel current flow is depicted from entry V+/Vdd to exit at V−/Vss. In the structure shown, the source channels of the NiFET and the PiFET are long channels with a small cross-section. The drain channels of PiFET and NiFET are thin with a large cross-section. The two channel current injection points are shown as the NiPort and the PiPort, the output port is also shown. Current injected into any port or combination of ports will quickly change the accessible structure stack port voltages.

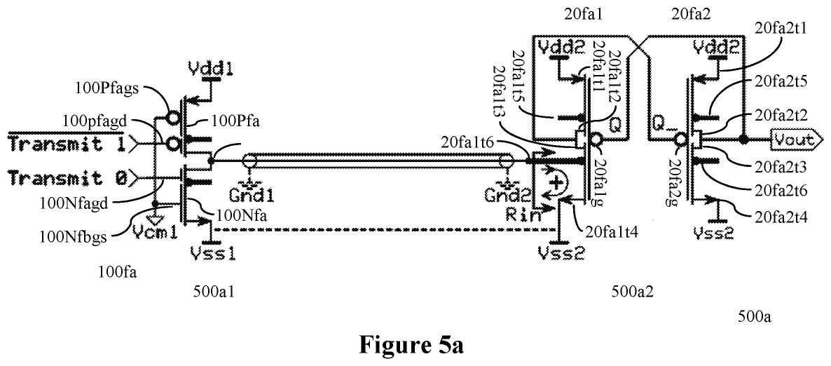

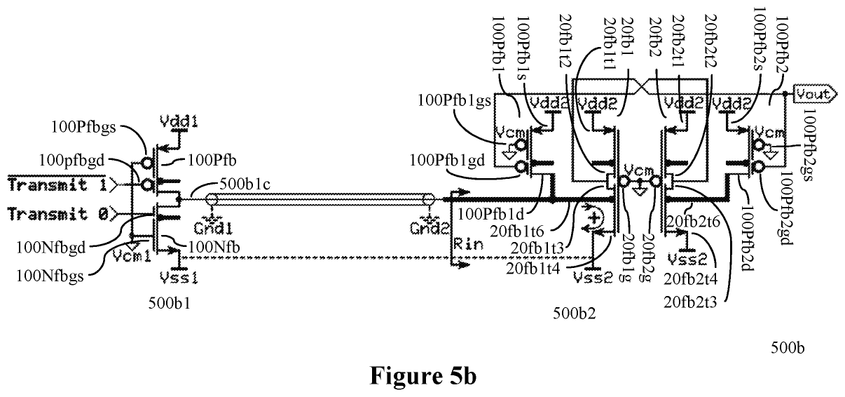

FIG. 5b shows a circuit arrangement for transmission of logic current signals.

Referring to FIG. 5b, the circuit comprises a transmitter 500b1 and receiver 500b2. The transmitter 500b1 and the receiver 500b2 may be constructed from a single CiFET/CsiFET structure or may be constructed using substantially CiFETs/CsiFETs alone. The transmitter 500b1 comprises a complimentary pair of PsiFET 100Pfb and NsiFET 100Nfb where a drain 100Pfbd of the PsiFET 100Pfb and a drain 100Nfbd of NsiFET 100Nfb are connected together to form a current signal terminal 500b1c. A source channel gate 100Pfbgs of the PsiFET 100Pfb and a source channel gate 100Nfbgs of the NsiFET 100Nfb are biased to a common mode voltage Vcm1, while a drain channel gate 100Pfbgd of the PsiFET 100Pfb for receiving a voltage logic signal for Transmit 1 and a drain channel gate 100Nfbgd of the NsiFET 100Nfb for receiving a voltage logic signal for Transmit 0. The transmitter 500b1 is arranged to converts a voltage logic signal Transmit 1/Transmit 0 into a bidirectional current signal that flows inward for a (“1”) and outward for a (“0”) through the current signal terminal 500b1c, and introduces a new state where no current flows. This new state brings a bionomic capability to logic circuits where it is desired to only use energy when information is being transmitted. No current in or out means no new information. In a power conserving fashion using a 3-State transmitter, which incorperates a No-Change state, along with a latching receiver statistically cuts the average signal power in half. The receiver 500b2 comprises a pair of CiFETs 20fb1 and 20fb2, and a pair of PsiFETs 100Pfb1 and 100Pfb2. The sources 20fb1t1 and 20fb2t1 of CiFETs 20fb1 and 20fb2, respectively, and sources 100Pfb1s, 100Pfb2s are connected to power supply, Vdd2. The gates 20fb1g and 20fb2g are coupled to the common mode voltage, Vcm. The source channel gates 100Pfb1gs and 100Pfb2gs are also coupled to the common mode voltage, Vcm. The drain channel gate 100Pfb1gd of the PsiFET 100Pfb1 is coupled to drain 20fb2t2 of the PiFET of the CiFET 20fb2 and to drain 20fb2t3 of the NiFET of the CiFET 20fb2; the NiPort 20fb2t6 of the CiFET 20fb2 is coupled to the drain of the PsiFET 100Pfb2; and the drain channel gate 100Pfb2gd of the PsiFET 100Pfb2 is coupled to drain 20fb1t2 of the PiFET of the CiFET 20fb1 and to drain 20fb1t3 of the NiFET of the CiFET 20fb1 to form output voltage, Vout. The current signal transmitted from the transmitter 500b1 is received at the drain 100Pfb1d of the PsiFET 100Pfb1 and the NiPort 20fb1t6 of the CiFET 20fb1 . The receiver 500b2 receives the current signal transmitted from the transmitter 500b1 and converts the current into volgate signal, Vout.

CTL current logic signals produce other current logic signal paths, or the signal current may be converted directly using the CiFET/CsiFET inherent current to voltage transforming capability/characteristics, often in logic circuits there is a switch between the two logic transfer states. This easy conversion from current to voltage (CtoV), current to current (CtoC), voltage to current (VtoC) and voltage to voltage (VtoV) logic states that is enabled with the CiFET/CsiFET allows new logic constructs that compress the physical logic implementation.

The CiFET/CsiFET device lends itself to implementing CTL as it can uniquely perform all the signal conversions CtoC, VtoC, VtoV and CtoV. Furthermore, the PiPort or the NiPort current injection port of the CiFET/CsiFET provides a current or voltage receiver whose input impedance (50 ohm→100 Kohm) can be designed into the silicon. The CiFET/CsiFET directly converts the logical current signal into a logically defined voltage at its output common drain terminal.

A current logic signal transmitter can be constructed by using a PsiFET, connecting its drain to the path or wire interconnect, as shown in FIGS. 3a and 3c to any of a CiFETs receivers nodes, including the iPorts or even its output node with consideration to DC biasing levels (further details will be discussed below). In a similar fashion, a NsiFET may be used to construct a current logic signal transmitter as shown in FIGS. 3b and 3d by connecting its drain to the path or wire interconnect (further details will be discussed below). In FIGS. 5a and 5b, both types of these logic signal current sources are simultaneously connected to the path or wire interconnect and in turn their signal current is injected or withdrawn or no logic signal current is delivered to the receivers NiPort node (further details are discussed below). The logic's current through n-iPort 200Ni is then returned to complete the loop through Vss. The system ground as shown can be bypassed while the signal current passes through its protected pathway. Additionally, using the CiFET 20a as a logic construct the design is able to be logically switched by controlling the drain channel gate voltage while using the Vcm voltage statically or dynamically applied across the gate of the source channel which then defines that channels gate to source voltage defining how it will control and regulate the output current.

When using the CiFET as a current summing logic gate wired OR or AND structures are straightforward to implement with almost unlimited fan in which helps to reduce interconnects and logic receiver transmitter counts. Employing a current as the logical fan-in variable minimizes ½CV\hat{ }2 parasitic losses and ground noise logic signal injection all this while running at speed.

When a voltage logic signal is used, all the transient supply noise adds into the net logic signal and reduces the effective noise margin. In a current logic signal-based system current loops carry the signal without being directly affected by the supply voltage noise or the noise found on the ground lines. The CiFET physical circuit swings centers around its common mode voltage when the CiFET is operated first as a linear element then as a logic element. By swinging about this circuit generated common mode voltage the signals avoid supply and ground system noises that decrease the circuit's effective noise floor.

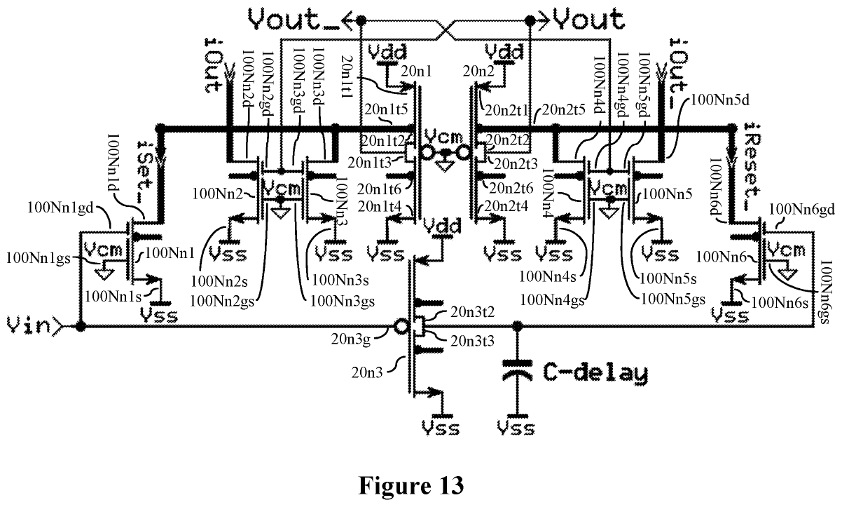

This same current logic can provide drive phase sensitive signals such as a clock trees thus allowing all receivers to be perfectly synchronized and helping to eliminate clock tree phase variation, circuit complexity and consumed power all while aiding the clock tree optimization process. This is shown in FIG. 13 and discussed in the corresponding description.

From an integrated system operational perspective, its wide temperature operating range of the CiFET/CsiFET, beyond the (−50 C to 175 C) of most of the Mil-Spec requirements means the circuits can run hotter or colder than possible with traditional CMOS logic circuits. The CiFET device is also quite tolerant of respect to parametric variations incurred during manufacturing due in great part to the circuit's capability to generate its own common mode voltage Vcm, which occurs when the feedback connected inverter that generates the common move voltage Vcm has its maximum gain, this common mode voltage Vcm is then used to bias the other parts of the system thus compensating for silicon parameter variations.

### Using Current for Logic Signals Instead of Voltage.

The limitations and the success of using “1” & “0” voltages to define logic levels and communicate logic signals over the interconnect wiring between logic elements are widely available. The CiFET/CsiFET as a logic element can be used for voltage levels. And most importantly, the CiFET/CsiFET can be used as current levels or even discrete packets of charge, when capacitance added across the latch to denote the logic levels of “1” and “0” where a packet of charge is used to trip the flip flop. The CiFET/CsiFET as a logic current receiver is shown in FIGS. 5a and 5b.

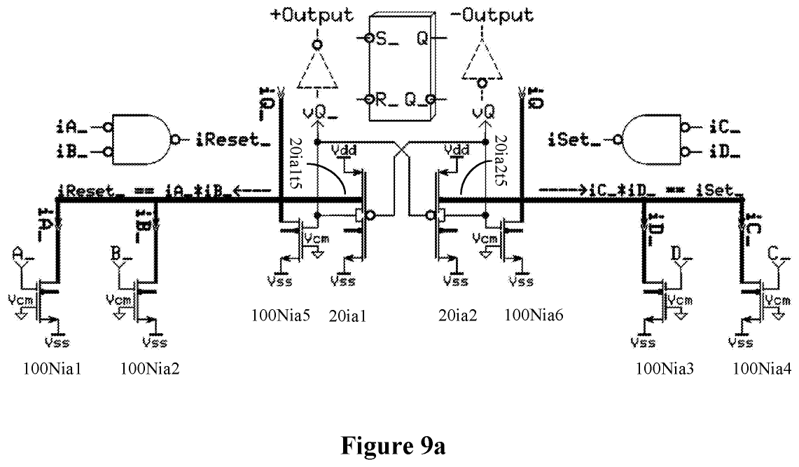

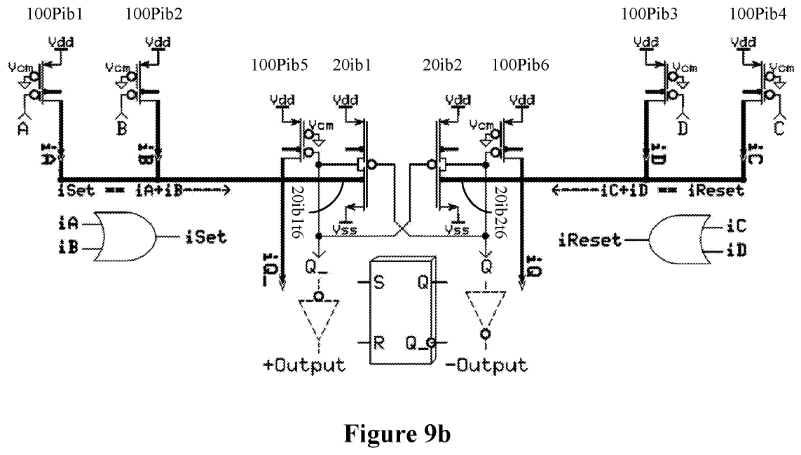

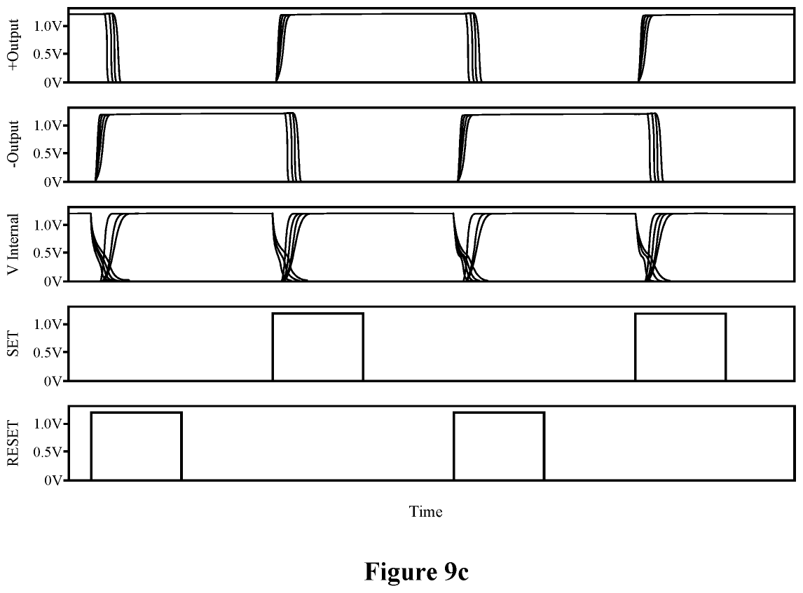

FIG. 9a shows a CiFET/CsiFET CTL voltage-holding-LATCH with wire-AND logic-voltage and logic-current logic input/output interfaces, where CiFET/CsiFET terminates the input logic current/charge transfer while operating as a logical NOR or NAND function. FIG. 9b shows a CiFET/CsiFET CTL voltage-holding-LATCH with wire-OR logic-voltage and logic-current logic input/output interfaces, where CiFET/CsiFET is the source of logic charge transfers depicts a NOR within an OR function using both voltage and current logic signals.

When a current signal is transmitted over interconnect wiring the positional segment wire voltage changes by its distributed impedivity and does not significantly change segment to segment, thus the effects of coupling interconnect wire parasitic displacement capacitance current, (I=CdV/dt+VdC/dt), is dramatically reduced. As a logic current node receiver, the CiFET presents a low impedance node making it hard for displacement currents, which often originate from a high impedance voltage source, to impact the signal current. This produces unique noise immunity for current based logic as noise sources are, in a manner power, tested as they try to add their currents to the signal current, but their impedance mismatch places those sources at a marked disadvantage.

The CiFETs current logic receiving node may sum different local noise loop currents as well as the desired logic current signal but their contribution to the noise floor erosion can be controlled. The CiFET current receiver is monitoring for that change in closed loop current it shares with the transmitter. CiFETs current small signal node voltage is secondary to the operation of the underlying logic current signals. The low input impedance of the logic receiver shorts out the high impedance voltage noise sources that often plague voltage-based logic with large transient noise spikes of fast logic. This type of preferential transient noise suppression is inherent to the current sensing logic technique; it has no counterpart in voltage-based logic techniques. For radiated point sources voltage injected noise intensity drops off as 1/r, the distance from the emitter. Current injected noise relies on the driving E field and thus drops off as 1/(r\hat{ }2) the distance from the emitter. The CiFET/CsiFET logic technique based on current levels which is the flux density which in turn is the electric field times the local conductivity. Displacement current injection capability falls off faster than the projection of a noise source to a high impedance receiving node.

As the CiFETs current driven node voltages do not change, much, the losses and drive needs of the parasitic capacitances are reduced. As a result of this, importantly, the CiFET/CsiFET logic circuits offer the capability of not increasing the base current, much, as the data rate of the logic signals increase.

As heat dissipation is the limiting design feature in computational throughput considerations CiFET/CsiFET logic offers predictable heat generation over a wide range of frequencies, it uses current mode logic to reduce ½CV² losses and with its extremely wide temperature operating range it is able to operate at higher temperatures reliably.

The CiFET family fundamentally changes design capability and provides a path to circumvent many speed limiting steps by increasing circuit layout density shortening signal paths. This new speed without the increase in power will be keenly felt in the area of IC design when in circuit timing reckonings, or timing closure limitations are evaluated.

CiFET/CsiFET logic designs present improvements on several levels. CiFET digital and CiFET analog constructs use the exact same standard process the hosting CMOS digital transistors provide with no process extensions. If a process node can produce a complementary CMOS pair, it can be used to produce the CiFET structure; however, an inverter made from the CiFET transistor has about a 20× gain advantage over its CMOS counterpart. CiFET digital and analog circuits are compatible at the most basic fabrication level. Analog and digital systems can be fabricated and interconnected on the same chip. With most interconnections mode internally on the chip external system connections are reduced and with that S/N of the system will increase as there are fewer high impedance noise entry point nodes. Analog to digital processes that combine the two worlds will be able to design with the same process node decks.

CiFET circuits produce and use a self-generated common mode reference voltage against which logic signals are referenced. This common voltage becomes very convenient as it is a quiet reference line against which the (“1”,“0”) response is given and judged by. Binary logic becomes anything above Vcm is a (“1”) and anything below Vcm is a (“0”) subject to complex system noise margin considerations, and those could be addressed by the Schmitt trigger detection described later.

This common mode rail is dispersed may be driven by several displaced common mode generators as shown in FIGS. 1a, 1b and 1c. In a complex system, there may be more than one such common mode voltages that are generated. Biasing levels, logic detection thresholds are just a few parameters that are affected by modulating the common mode voltage. This common mode voltage rail is isolated from the noise transients caused by high current pulses on the systems supply busses. The system reference is uniquely isolated from both the positive and negative power supply and the spurious noises that they often carry. This technique further decreases noise floor of circuitries in accordance with the present invention. The common mode voltage generator produces places the CiFET/CsiFET logic in the highest transResistance gain (rm) portion of its transfer function. Fast logic needs to operate at the circuit's highest gain point or shifted off that point for other overall waveshape transfer function considerations.

The speed and drive power of the CiFET/CsiFET logic can be dynamically controlled from within the systems associated logic circuits. As a higher bandwidth is needed in the CiFET's/CsiFET's logic, speed and power consumption can be adjusted dynamically by changing the supply voltage. For the highest computational throughput, the supply voltage is limited by the gate oxide breakdown.

Uniquely whole sections of CiFET/CsiFET logic can be easily turned completely off and turned on in less than a microsecond. This is accomplished by switching the gate M3g of the P-channel source transistor M3 channel from Vcm to Vdd. CsiFET digital performance and power consumption lends itself to programmatic control as illustrated in FIGS. 3a, 3b, 3c and 3d.

CiFET/CsiFET logic interfaces seamlessly with traditional CMOS chip level logic. CiFET/CsiFET logic is born from it hosting CMOS process node. CiFET/CsiFET logic structures easily implement almost unlimited NOR and NAND fan-in capability. CiFET/CsiFET logic is adept at operating in both voltage mode and current mode.

The CiFET/CsiFET logic structure allows several modulation input ports. Specifically, the N and P iPorts currents can be used to shift the operating point of the digital logic. Current may be injected or withdrawn from each of the iPorts, which allows that logic element parameters to be functionally modulated. This feature adds to the dynamic reconfiguration of the CiFET family. Detection thresholds can be dynamically changed adding a different mode to the intrinsic capabilities of the CiFET/CsiFET logic family.

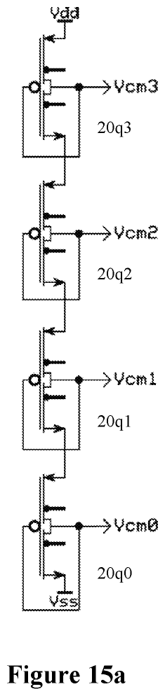

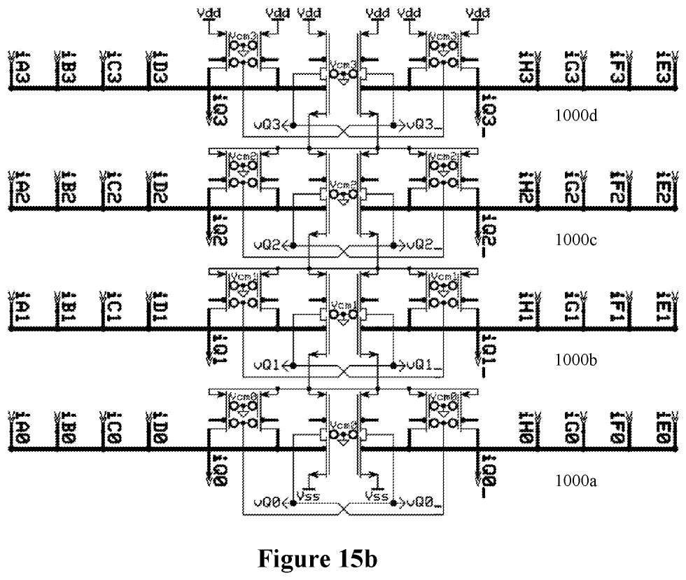

The CiFET's capability to operate at low voltage make it is possible to stack several CiFET's in series between a modest Vdd and Vss. CiFET/CsiFET logic and latches will operate and hold state with (Vdd-Vss<250 mv), the speed of operation falls with the supply voltage. The series stacked CiFET/CsiFET logic circuits separated by different common mode voltages can run channels of parallel logic if desired see FIG. 15.

It has been demonstrated that the CiFET/CsiFET logic can make D flip flops, RS flip flops and latches and therefore the CiFET can be used to make memory cells and memory storage structures using the CiFET latches as the storage element. For SRAM and other latches, only one-bit line is needed because you can push current into the iPort of the cross-coupled CiFET latch to set it to ONE, or pull current out of the same iPort to set a ZERO into the latch.

CiFET digital logic is compatible with an erasable FPGA structure. Additionally, functional sections of CiFET analog and CiFET digital logic are both compatible with FPGA technology.

The basic CMOS structure source, channel, drain and gate have been fabricated on substrates that range from carbon nanotubes to conductive spray on structures delivered with an ink jet type printer. If a complimentary CMOS structure can be constructed a complimentary CiFET structure can be constructed as one needs only to physically place another drain or source type diffusion in the channel carefully to implement an iPort in each of the respective channels. When these CiFET structures are biased to a self-generated common mode voltage they are biased to their maximum value transfer function. This is true whether the CiFET structures are built from silicon, carbon nanotubes, printed conductive inks or any organic or inorganic grown structure. CiFET/CsiFET logic circuits could be printed on flexible substrates and used to provide the logic for disposable point of contact devices.

FIG. 1a illustrates a CsiFET structure 100a, which is similar to a CiFET, having the n-channel transistor source connected to Vss is commonly called M1 and naming up throught M2, M3 and finally M4 whose p-channel source is connected to Vdd. The gates M1g, M2g, M3g and M4g of M1, M2, M3, and M4, respectively, are connected to the common mode voltage Vcm. As imaged this CsiFET 100a is completely biased for operation. Current injected into either the PiPort 100aPi or the NiPort 100aNi will cause the Vout 100aout voltage to increase and move toward Vdd. If current is pulled from either of the nodes the Vout voltage will begin to drop toward Vss.

Referring to FIG. 1b and in FIG. 1c, the circuit symbol for a CiFET 20a is presented. Both circuits 100b in FIG. 1b and 100c in FIG. 1c shows that CiFET 20a is connected in such a way that CiFET 20a would produce the self generated common mode voltage Vcm. In a circuit system Vcm would be distributed around the circuit much like Vdd and Vss might be, without the buffering capacitors though. Drive capacity could be added to this distribution as necessary in the design phase as needed.

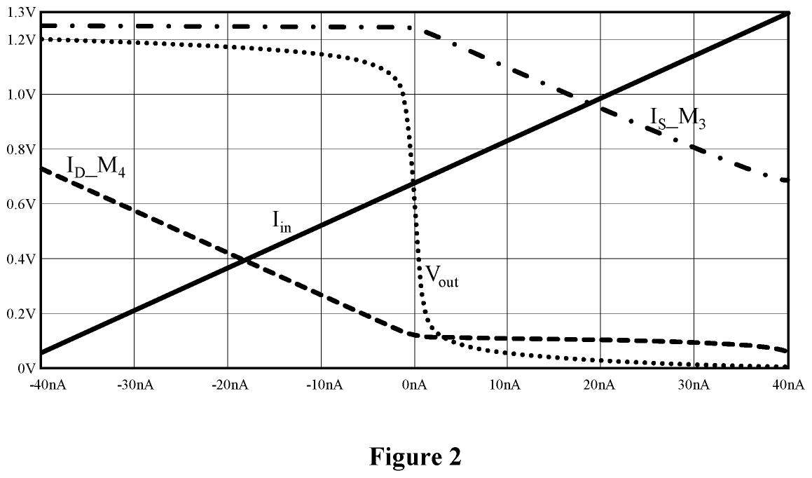

In FIG. 2, a separate CsiFET biased into operation by the Vcm applied to its common gates is depicted both in a circuit and in its operational graphs. Not much account will be made of the specific current and voltage values as they can be adjusted by changing several aspects of the CsiFET designed structure. However, no matter what the specific values are the CsiFET will show the operational curves that are shown for this circuit. An input ramp current from a negative value, to a positive value is applied to an iPort, in this case it is applied to the PiPort. As current is pushed into the node the Vout is driven toward Vdd as this signal current becomes 0, the Vout of the CsiFET becomes Vcm and as current is pulled from the iPort the Vout is driven toward Vss. Shown in the graph is the distribution of current into the PiPort node. These current will all sum to zero and include the injected signal current the current from the P-channel source outer CsiFET channel and the current entering the source node of P-channel drain counterpart channel.

As can be seen, the CsiFET is an active device with 4 channels produced by diffusing precisely an extra node in each of the hosting CMOS process node's complimentary inverting pair. The outer complementary source channels sets the nodes input resistance and regulates the channel current because of their fixed gate to source voltage. The inner drain channels operate as a common gate amplifier voltage gain stage. Current into the iPort resistance modulates the source voltage driving the drain voltage to linearly change. Non-linearities mathematically cancel because the change in the common drain output voltage is driven in a complementary fashion. It must be noted that common gate amplifiers are driven by the source voltage.

The basic CsiFET logic supports a PiPort and an NiPort current inject. Current injected into either of these nodes will cause the Vout node to move toward the Vdd rail, similarly current drawn from either these nodes will cause the Vout node to move toward the Vss rail. The input impedance seen at these two ports can be tuned to application needs by means of adjusting the iRatio which describes the position of the new node diffusions in the channels. While the input impedance is fixed at fabrication the presented input impedance can be dynamically adjusted by modulating that CsiFET sectional supply voltage. The standard input impedance can easily be designed to be 50 ohms. These nodes are used to control the performance of the Vout with incoming or outgoing current flows. CsiFET can also be controlled by driving the high input impedance common gate node with a voltage signal. The common mode voltage used to bias the CsiFET to its maximum transresistance gain is also shown, there may be more than one Vcm generators to accommodate Vcm loading limitations. However due too the wide tolerance of the CsiFET vs bias point vs linearity small variations between different Vcm generators are of little concern. This tolerance to parameter variation also applies to process node variations. In addition to met different design goals, speed, logic thresholds or others the specific common mode voltage generator can be tuned to its local circuits needs.

FIGS. 3a, 3b, 3c and3d illustrate several circuit arrangements by utilizing siFET (PsiFET or NsiFET) that change a voltage logic level into a controlled current signal suitable for carrying logic level information. Referring to FIG. 3a, PsiFET 100P is arranged to convert voltage input Vin into the current output Iout. The PsiFET 100P comprises a source channel transistor M4 and a drain channel transistor M3. The source M4s of the source channel transistor M4 is coupled to the voltage supply Vdd. The drain M4d of the source channel transistor M4 is coupled to the source M3s of the drain channel transistor M3. The source channel gate 100Pgs is coupled to common mode voltage Vcm, while the drain channel gate 100Pgd is arranged to receive input voltage, Vin. The drain M3d of the drain channel transistor M3 provides the current output, Iout, which corresponds to the voltage input Vin. PiPort 100Pi is provided between the source channel transistor M4 and the drain channel transistor M3.

The circuit shown in FIG. 3c is equivalent to the one shown in FIG. 3a, where PsiFET 100P is arranged to convert voltage input into current, where the source 100Ps is connected to the supply Vdd, the source channel gate 100Pgs is coupled to common mode voltage, Vcm, and the drain channel gate 100Pgd is arranged to receive input voltage Vin. The drain 100Pd provides current output PiOut that corresponds to the input voltage Vin.

Referring to FIG. 3b, NsiFET 100N is arranged to convert voltage input Vin into the current output Iout. The NsiFET 100N comprises a drain channel transistor M2 and a source channel transistor M1. The source M1s of the source channel transistor M1 is coupled to the voltage supply Vss. The source M2s of the drain channel transistor M2 is coupled to the drain M1d of the source channel transistor M1. The source channel gate 100Ngs is coupled to common mode voltage Vcm, while the drain gate 100Ngd is arranged to receive input voltage, Vin. The drain M2d of the drain channel transistor M2 provides the current output, Iout, which corresponds to the voltage input Vin. NiPort 100Ni is provided between the source channel transistor M1 and the drain channel transistor M2.

The circuit shown in FIG. 3d is equivalent to the one shown in FIG. 3b, where NsiFET 100N is arranged to convert voltage input into current, where the source 100Ns is connected to the supply Vss, the source channel gate 100Ngs is coupled to common mode voltage, Vcm, and the drain channel gate 100Ngd is arranged to receive input voltage Vin. The drain 100Pd provides current output NiOut that corresponds to the input voltage Vin.

The current level can be controlled and dynamically modulated if necessary by changing the Vdd into which one works or draw current from in addition to the many ways design may be effected by the device'sF iRatio (definition of iRatio is shown below) that is ultimately cast into silicon. These current sources and current sinks are shown either the active part of a full CiFET/CsiFET with designed iRatios that render one half of the CiFET/CsiFET essentially passive or the structure is indeed one half of the CiFET/CsiFET with the appropriate channel retained for the job of a current sink or source.

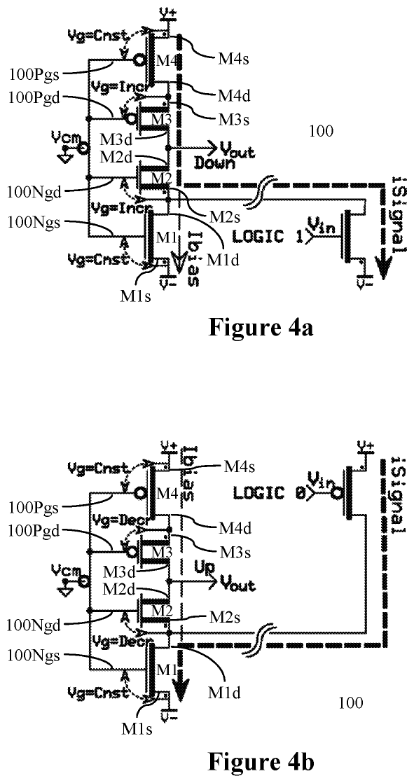

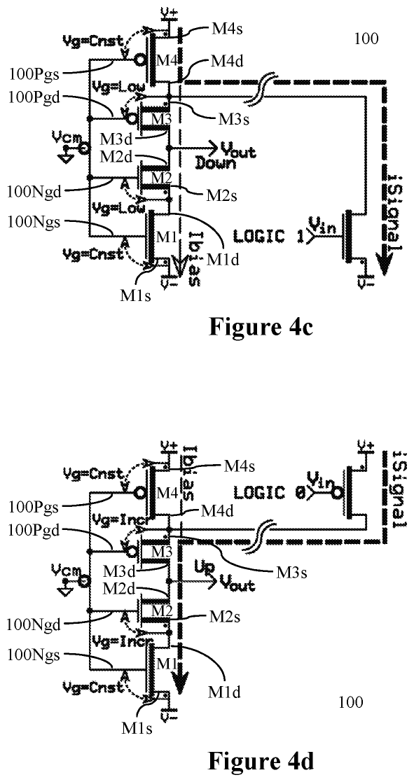

The siFET logic current sources shown in FIGS. 3a, 3b, 3c and 3d provide controlled signal current, regulated by the Vcm controlled transistor and the logic signal driven transistor. In FIGS. 4a, 4b, 4c and 4d, a single transistor current logic signal source is shown. This type of current signal source omits the Vcm current regulation and uses the full unregulated current drive capability of a such a designed transistor. This structure would be used where maximum logic speed is required.

FIGS. 4a, 4b, 4c and 4d show simplified schematic diagrams that converts current signal into voltage. These voltage to current devices are suitable when driving the wired OR and AND structures described later. When adding another input to such a wired device only this sink or source is needed the receiver stays the same, this CiFET/CsiFET wired logic dramatically reduces silicon space for many array switching and accessing applications as well as those requiring clock synchronization.

FIGS. 4a, 4b, 4c and 4d also illustrate the full structure of a CiFET/CsiFET used for logic purposes coupled with a driving current sink or source. In these drawings is clear that another source or sink current generator could be added to drive its respective PiPort or Niport. This structure will be used to produce extensible wired OR, AND, NOR and NAND structures. Current flow is shown in bold dashed line, that current path is activated when the logic signal is presented.

Referring to FIGS. 4a and 4b, CsiFET 100 is arranged to convert the current signal iSignal (either “1” or “0”) into voltage output Vout. In this arrangement, the p-source channel gate 100Pgs, p-drain channel gate 100Pgd, n-drain channel gate 100Ngd and n-source channel gate 100Ngs are coupled to common mode voltage Vcm. Current signal iSignal is arranged to be received at the source M2s of the drain channel transistor M2 and the drain M1d of the source channel transistor M1. The drain M3d of the drain channel transistor M3 and the drain M2d of the drain channel transistor M2 provides output voltage Vout.

Referring to FIGS. 4c and 4d, the arrangements of the CsiFET 100 are the same as those shown in FIGS. 4a and 4b, except that current signal iSignal is coupled at the drain M4d of the source channel transistor M4 and source M3s of the drain channel transistor M3.

TABLE 1
Single CiFET/CsiFET logic state

| CiFET Logic Table | | | |
|---|---|---|---|
| Current | control | | |
| In | Out | Vout | Vout |
| null | null | Vcm | Vcm |
| In | | 1 | Vdd |
| Ip | | 1 | Vdd |
| In + ip | | 1 | Vdd |
| | In | 0 | Vss |
| | Ip | 0 | Vss |
| | In + Ip | 0 | Vss |
| In | Ip | Z | Vss < Z < Vdd |
| Ip | In | Z | Vss < Z < Vdd |

The CiFET/CsiFET as a logic element can be driven through several ports by voltage and current inputs simultanously. Currents may be sourced or sunk from each of the PiPort or the NiPort. Current flow into either or both of these ports will drive the Vout toward Vdd. Current flow out of either or both of these ports will drive Vout toward Vss. As this is a binary logic if one sinks current into one iPort and sources from the complimentary iPort the Vout state will be undefined. The sourcing or sinking current required to run the CiFET/CsiFET logic is that current when sourced or sunk to a iPort will drive the Vout to either Vdd or Vss to a level that is acceptable for the logics operation. As the thresholds of the logic levels may be dynamically adjusted these state definitions will depend on the specific circuit and logic developed. In addition the CiFET/CsiFET logic state may be controlled by applying a voltage other than Vcm to the common gate. If made more positive than Vcm the output will drop and if made more negative Vout will rise. As an additional state to the logic “0” and “1” the CiFET/CsiFET logic allows one to hold the common gates at Vcm and inject or withdraw no logic currents from either iPort and the Vout will return to its unperturbed Vout of Vcm. This could be considered an extra nothing is happening logic state.

FIG. 5a shows a schematic diagram of a circuit utilizing CiFET/CsiFET for a voltage data stream, which is turned into a current data stream and is transmitted across a transmission line with relatively little voltage variation along the transmission line as the data values of “0”, no current, and “1” current on are transmitted. A transmitter 500a1 converts voltage signal, Transmit 1/Transmit 0 into current data stream. The transmitter 500a1 comprises a CsiFET 100fa , where the source 100Pfas of PsiFET 100Pfa is coupled to the power supply Vdd1, the source 100Nfas of the NsiFET 100Nfa is coupled to Vss1. The source channel gate 100Pfags of the PsiFET 100Pfa and the source channel gate 100Nfags of the NsiFET 100Nfa are coupled to common mode voltage Vcm1. The drain channel gate 100Pfbgd of the PsiFET 100Pfa is arranged for receiving a voltage logic signal for Transmit 1 and the drain channel gate 100Nfagd of the NsiFET 100Nfa is for receiving a voltage logic signal for Transmit 0. The drain 100Pfad of the PsiFET 100Pfa and the drain 100Nfad of the NsiFET 100Nfa are coupled to together to form output for transmitting current data stream.

The receiver 500a2 comprises a pair of CiFETs, 200fa1 and 200fab. The sources 20fa1s and 20fa2s of CiFETs 20fa1 and 20fa2 are connected to power supply, Vdd2. The gate 20fa1g of the CiFET 20fa1 is coupled to the drain 20fa2t2 of the PiFET and the drain 20fa2t3 of the NiFET of the CiFET 20fa2; while the gate 20fa2g of the CiFET 20fa2 are coupled to the drain 20fa1t2 of the PiFET and the drain 20fa1t3 of the NiFET of the CiFET 20fa1.

These logic current levels are received at the receiver 500a2 by the NiPort 20fa2t6 of the CiFET 20fa1. This current is received via a low input impedance port, i.e. NiPort 20fa2t6. The receiving port impedance may be set at fabrication time and tuned dynamically during operation. Since current travels as a through variable in a loop and the receiver terminates locally to the receiver Vss2 supply, ground noise is between the transmitter Vss1 and Vss2 does not enter as directly into the received signal noise margin like conventional voltage logic transmission systems. The current, due to the CiFET transresistance transform (rₘ) is converted directly into a output voltage to be used elsewhere in the circuit.

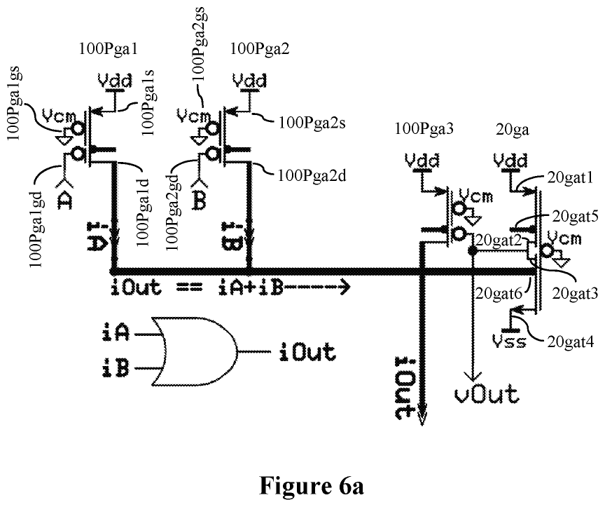

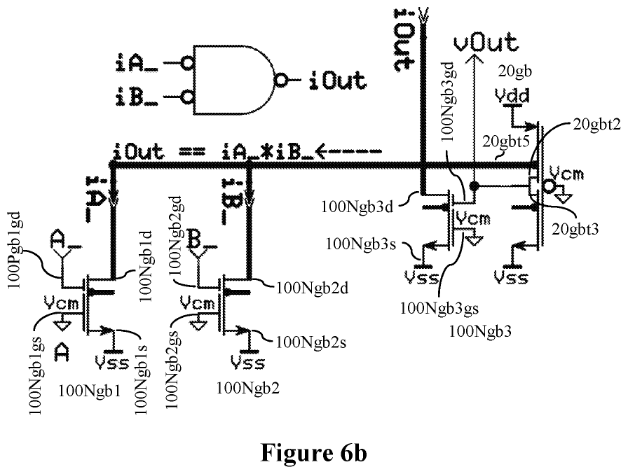

FIG. 6a shows a schematic diagram of a wired OR circuit with voltage-level and current level logic input, the input logic variables are supplied by voltage to current output convertors where the output current drives the wired OR logic rail. Additional current sources may be interfaced to the wired OR logic rail. PsiFETs 100Pga1, 100Pga2 and 100Pga3 are arranged to convert voltage to current, the same arrangement are as shown in FIG. 3c. For example, a first logic input A is converted to a current iA by the PsiFET 100Pga1, while a second logic input B is converted to a current iB by the PsiFET 100Pga2. The logic input currents iA and iB are coupled and are fed to NiPort 20gat6 of CiFET 20ga for converting the current iA+iB into logic output voltage Vout. PsiFET 100Pga3 converts the Vout into the logic output current iOut.

FIG. 6b shows a schematic diagram of a wired AND circuit. The input logic variables are supplied by the logic voltage inputs (A, B). These logic signals are supplied by voltage to current output convertors NsiFET 100Ngb1, 100Ngb2, 100Ngb3 which are arranged to convert logic voltage A, B to current iA_ and iB_, the arrangement of which is shown in FIG. 3d. The output current iA_ and iB_ drive the wired AND logic rail, or PiPort 20gbt5. This CiFET/CsiFET logic element supplies both a current controlled logical output state and a voltage logic level output. Additional current sources are easily interfaced to this wired AND logic rail. The logic signal is a current and eventually a completed loop the current logic signal inherently shuns displacement current noise. The noise being a high impedance source vs the CiFETs iPort adjustable but in this receiver use case that input impedance would be designed to be a low impedance iPort. This node impedance is designed in and can range from less than 50 ohms to more than 100 kohms. The nodes DC output bias voltage will also change from a few millivolts to 100's of millivolts depending on the circuits Vdd, the CiFET/CsiFET design bias and can be dynamically changed by in circuit adjusting its Vdd from another controlling circuit. CiFET/CsiFET logic in different cases can be driven by voltage to voltage, voltage to current, current to current of current to voltage. These four modes of operation are all possible ways of handling the logic data streams. This complete inter-changeability of data drive modes offers unique capabilities to the digital logic designers. All four modes of operation are possible within the CiFET transistor structure proper, using this single transistor one can move through these logic transmission modes within the logic process hardware pathways.

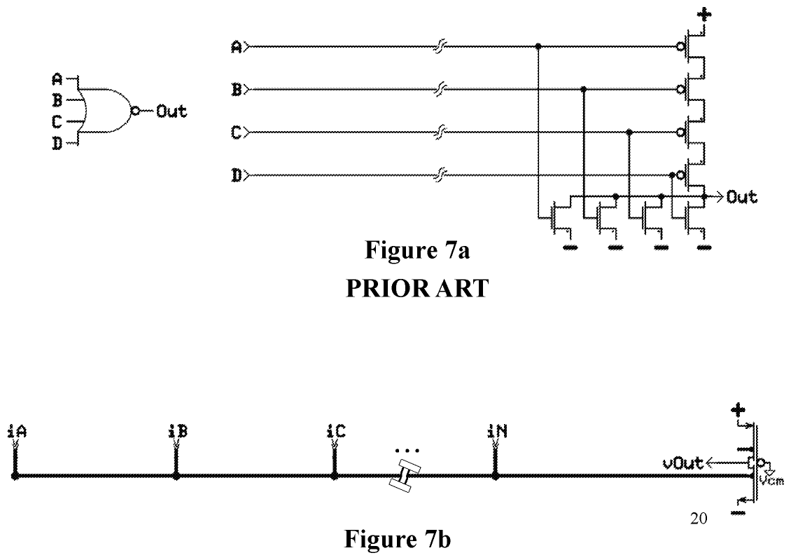

FIG. 7a illustrates a schematic diagram of a 4 input CMOS NOR logic gate, and FIG. 7b illustrates a schematic diagram of NOR logic gate using CiFET. Referring to FIG. 7a, in the CMOS logic case, the circuit grows rapidly in size as the number of NOR inputs are increased, this increase in size must also include the size of the incoming logic transmitters and must also include considerations for the associated increase in parasitics and the increase in transistor size as it must drive these capacitances. In contrast, as shown in FIG. 7b, the CiFET 20 is wired and arranged to function as a NOR logic element, which would remain constant in size as additional current logic sources enter their logic data onto the single interconnect wire or collection wire. The silicon size is decreased and CiFET wired logic gates allow a very large fan in capability, 25 inputs would not be unrealistic.

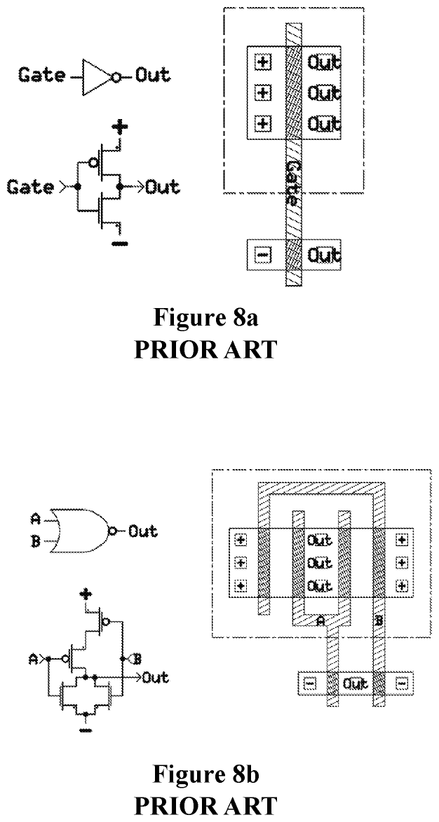

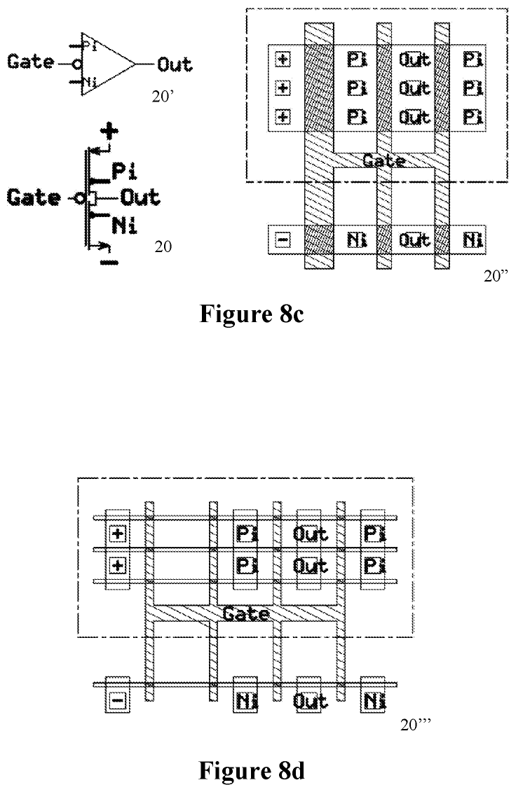

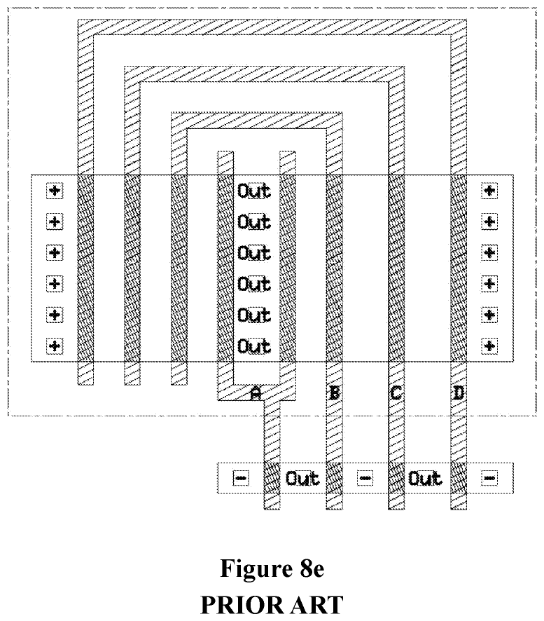

FIGS. 8a to 8b demonstrate the respective silicon surface area taken up by the several different logics of CMOS and FinFET. It is to be noted how when CMOS is called upon to move from a 1 (one) input NOT gate to a 2 input NOR gate, the required Silicon surface area grows disproportionately and, in time, CMOS would provide a limit to the fan in of such a CMOS logic structure. The same would be true for the FinFET structure. However as shown in FIG. 7b, the CiFET wired NOR gate consists of a wire into which the summed currents of the NORs inputs are collected. The fan in of such a CiFET structure can be designed to accommodate any design needs.

FIG. 8c illustrates a CiFET device 20, 20′and silicon layout plan 20″ relating physical size in planar CMOS. FIG. 8d illustrates the CiFET device 20′″ and silicon layout plan relating physical size in FinFET technology.

FIG. 8e presents the CMOS layout of a 4 input OR logic gate. Comparing it with the layout shown in FIG. 8b, it would be apparent that the size increase as the number of input terminals increases is evident. The silicon circuit for the CiFET 4-input NOR gate is basically the same as that for an NOR gate with n number of inputs, the only addition to the circuit illustrated in FIG. 7b is the logic transmitter's connection to the wired collection wire.

The input trip current SET pulse is drawn from the transmitter illustrated in FIGS. 5a and 5b. The choice is based on the design needs; the DC port voltage at the PiPort is higher than that found at the NiPort. This input trip current can range from 100's of Picoamps to micro amps depending on the speed needs of the underlying circuit. That trip current drives the output of the common drain connection down toward Vss that in turn shuts down an iFET/siFET serving as a logic voltage to current convertor which is cross feedback the adjacent CiFET/CsiFET corresponding driven port, this feedback action quickly snaps the CiFET/CsiFET flip flop into the set state, in a similar fashion a reset current pulse withdrawn from the corresponding iPort will reverse the state of the CiFET/CsiFET flip flop to the reset state.

Flip Flops have been simulated to run on 100's of nanoamps and still operate at speeds into the 100 khz region, whereas with other flip flops with different iRatios have needed micro amps to trip the flip flop and operate at speeds in the multiple GHz region. This uniquely wide design flexibility widens the applications to which CiFET/CsiFET logic can be brought to bear. CiFET the designs can adjust the Vdd-Vss voltage to reach their overall power objectives with minimal impact on the net speed and noise immunity because in part due to the property that with current based logic node voltages do not change. Power loss through radiated displacement current must be considered in the circuit's power budget as well as the RF problems caused by the multiple nodal noise antennas produced by those changing node voltages. The CiFET/CsiFET logic Flip Flop structure adds the iRatio, the P-Channel multiplier ratio, the settable Vcm and the ability to dynamically change some of these parameters to the designers set of tools that can be modified to meet the designs overall goals based on speed, overall power consumption, supply voltage availability and operating temperature requirements.

CiFET/CsiFET logic offers a new logic state of no current in (“1”) or current out (“0”), it enables the design to include simultaneously if necessary both current based logic paths and voltage-based logic paths. The CiFET/CsiFET logic can operate with supply voltages of less than 250 mv. Testing has confirmed CiFET operation with temperatures ranging −80 to 220 degrees centigrade. CiFET current based logic interfaces with the hosting voltage mode CMOS logic with its voltage logic level outputs.

Referring to FIG. 9a, the latch combines a wired 2 input AND gate is shown as the input to the (set) and the wired 2 input AND gate is shown as the input to the (reset). Inputs (A_, B_, C_, D_) turn a voltage level into a current input (iA_, iB_, iC_, iD_) to the respective wired gate. Logic voltage to logic current conversions are carried out by NsiFETs 100Nia1, 100Nia2, 100Nia3, 100Nia4, 100Nia5 and 100Nia6, all of which are arranged in the same way as shown in FIG. 3d. For example, inputs A_, B_, C_ and D_ are converted to current iA_, iB_, iC_ and iD_ by NsiFETs 100Nia1, 100Nia2, 100Nia3, 100Nia4, respectively. A pair of CiFETs, 20a1 and 20ia2 are arranged to form a latch, where current converted reset signal iReset_ is received at PiPort 20ia1t5, where the set signal, iSet_ is received at the PiPort 20ia2t5. Vout from CiFET 20a1 is VQ_, which is fed to NsiFET 100Nia5 for converting the voltage into current iQ_, while Vout from CiFET 20ia2 is VQ, which is fed to NsiFET 100Nia6 for converting the voltage into current iQ. Accordingly, the output of the latch would be presented in both a voltage level “1” & “0” and as a current level (“0” no current, “1” current) logic signal.

Similarly, the latch in FIG. 9b combines a wired 2 input OR gate is shown as the input to the (set) and the wired 2 input OR gate is shown as the input to the (reset). Inputs (A, B, C, D) turn a voltage level into a current input (iA, iB, iC, iD) to the respective wired gate. Logic voltage to current conversions are carried out by PsiFETs 100Pib1, 100Pib2, 100Pib3, 100Pib4, 100Pib5 and 100Pib6, all of which are arranged in the same way as shown in FIG. 3c. For example, inputs A, B, C and D are converted to current iA, iB, iC and iD by PsiFETs 100Pib1, 100Pib2, 100Pib3, 100Pib4, respectively. A pair of CiFETs, 20ib1 and 20ib2 are arranged to form a latch, where current converted reset signal iReset is received at NiPort 20ib2t6, where the set signal, iSet is received at the NiPort 20ib2t6. Vout from CiFET 20ib1 is Q_, which is fed to PsiFET 100Pib5 for converting the voltage into current iQ_, while Vout from CiFET 20ib2 is Q, which is fed to PsiFET 100Pib6 for converting the voltage into current iQ. Accordingly, the output of the latch would be presented in both a voltage level “1” & “0” and as a current level (“0” no current, “1” current) logic signal.

FIG. 9c shows plots that demonstrate the voltage-holding-LATCH −170° C., −55° C., 25° C., 125° C., & 275° C. example-waveforms. The graphs in FIG. 9c refer to the circuit in FIG. 9b and are the output of simulation runs at these various temperatures. The temperature range was varied, in centigrade, from −170 C.°, −55 C.°, 27 C.°, 125 C.° to 270 C.°. The plots starting from the bottom show the reset voltage pulse of either voltage logic input C or D. The second plot from the bottom shows the set voltage pulse of either voltage logic input A or B. The middle traces show raw Q and Q_ outputs of the actual latch. The second trace from the top is the buffered output of the latches Q output. The top trace is the buffered output of the Q_latch output.

Further referring to FIG. 9c, the simulations were run across a wide temperature range as indicated above. On the top trace multiple curves are shown as they drop from a logic state (“1”) to logic state (“0”). The leftmost downward trace corresponds to the −170° C. simulation, the next to the −55° C. simulation, and the next to the 27° C. simulation. What seems to be the last downward trace, the further most right downward transition is actually the traces for the 125° C. simulation and the 270° C. simulation. To operate over this wide temperature range, the CiFET/CsiFET latch shown in FIG. 9a, and FIG. 9b require milliampere bias current levels.

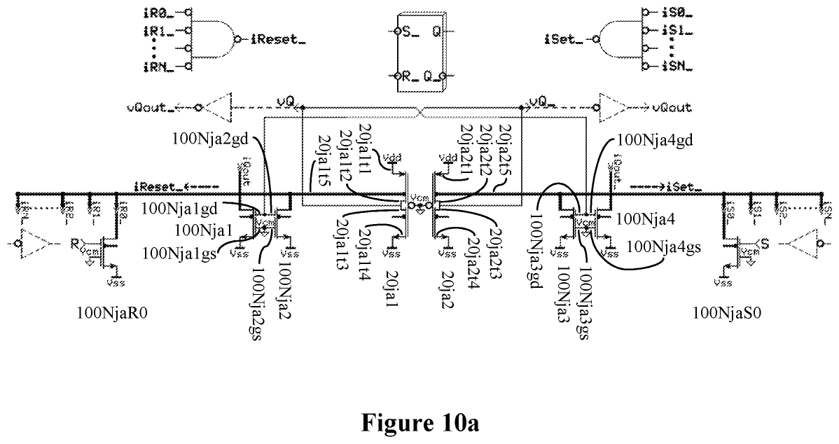

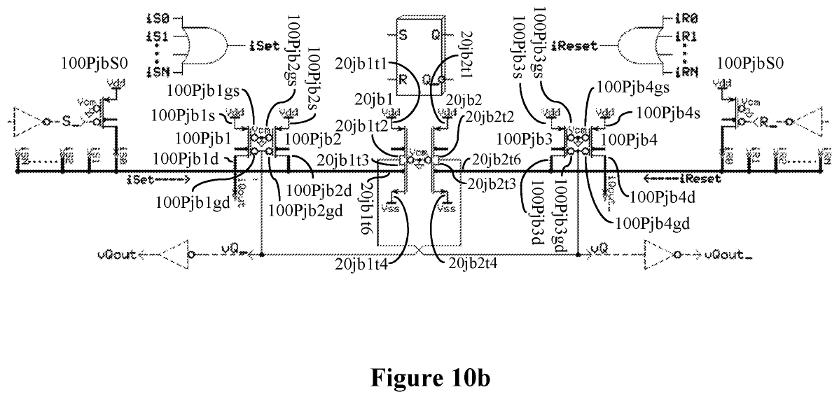

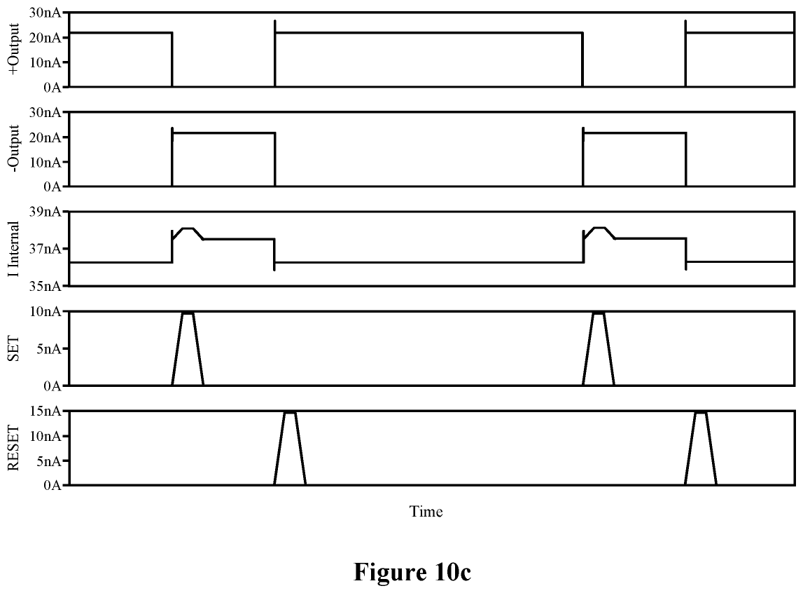

FIG. 10a illustrates a schematic diagram of a CTL full-current-mode wire-AND high-fan-inn LATCH with I/O options for high-bus-traffic & high-speed. A wired multiple input AND gate is shown as the input to the (reset) and a wired multiple input AND gate is shown as the input to the (reset). Inputs (R0, R1, R2, . . . RN) are converted into current (iR0_, iR1_, iR2_, . . . iRN_). Similarly, inputs (S0, S1, S2, . . . SN) are converted into a current input (iS0_, iS1_, iS2_, . . . iSN_). Logic voltage to current conversions are carried out by NsiFETs 100NjaR0, 100NjaR1, 100NjaR2, . . . 100NjaRN, 100NjaS0, 100NjaS1, 100NjaS2 . . . 100NjaSN, all of which are arranged in the same way as shown in FIG. 3d. For example, inputs R0, R1, R2, . . . RN are converted to current iR0_, iR1_, iR2_, . . . iRN_ by NsiFETs 100NjaR0, 100NjaR1, 100NjaR2, . . . 100NjaRN, respectively; while inputs S0, S1, S2, . . . SN are converted to current iS0_, iS1_, iS2_, . . . iSN_ by NsiFETs 100NjaS0, 100NjaS1, 100NjaS2, . . . 100NjaSN, respectively.

A pair of CiFETs, 20ja1 and 20ja2 and a first pair of NsiFETs 100Nja1 and 100Nja2, and a second pair of NsiFETs 100Nja3 and 100Nja4 are arranged to form a latch, where gates of CiFETs 20ja1 and 20ja2 are coupled together to common mode voltage Vcm; sources 20ja1t1 and 20ja2t1 of PiFETs of CiFETs 20ja1 and 20ja2, respectively, are coupled to Vdd, and sources 20ja1t4 and 20ja2t4 of NiFETs of CiFETs 20ja1 and 20ja2, respectively, are coupled to Vss. The first pair of NsiFETs 100Nja1 and 100Nja2 are arranged together where the source channel gates 100Nja1gs and 100Nja2gs are coupled together to common mode voltage Vcm; and sources 100Nja1s and 100Nja2s are coupled to Vss. Similarly, the second pair of NsiFETs 100Nja3 and 100Nja4 are arranged together where the source channel gates 100Nja3gs and 100Nja4gs are coupled together to common mode voltage Vcm; and sources 100Nja3s and 100Nja4s are coupled to Vss.

iR0_, iR1_, iR2_, . . . iRN_ form a reset current signal, iReset_; and iS0_, iS1_, iS2_, . . . iSN_ form a set current signal, iSet_. The reset current signal iReset_ is fed to the PiPort 20ja1t5 of CiFET 20ja1 and to drain 100Nja2d of the NsiFET 100Nja2; while the set current signal iSet_ is fed to the PiPort 20ja2t5 of CiFET 20ja2 and drain 100Nja3d of the NsiFET 100Nja3. Drain channel gates 100Nja1gd and 100Nja2gd are coupled with drain 20ja2t2 of PiFET and drain 20ja2t3 of NiFET of CiFET 20ja2 to form output voltage, vQ_; drain channel gates 100Nja3gd and 100Nja4gd are coupled with drain 20ja1t2 of PiFET and drain 20ja1t3 of NiFET of CiFET 20ja1 to form output voltage vQ. Drain 100Nja1d of the NsiFET 100Nja1 provides output current iQout, while the drain 100Nja4d of the NsiFET 100Nja4 provides output current iQout_.

FIG. 10b illustrates a schematic diagram of a CTL full-current-mode wire-OR high-fan-inn LATCH 1000 with I/O options for high-bus-traffic & high-speed. Inputs (R0, R1, R2, . . . RN) are converted into current (iR0, iR1, iR2, . . . iRN). Similarly, inputs (S0, S1, S2, . . . SN) are converted into a current input (iS0, iS1, iS2, . . . iSN). Logic voltage to current conversions are carried out by PsiFETs 100PjbR0, 100PjbR1, 100PjbR2, 100PjbRN, 100PjbS0, 100PjbS1, 100PjbS2 . . . 100PjbSN, all of which are arranged in the same way as shown in FIG. 3c. For example, inputs R0, R1, R2, . . . RN are converted to current iR0, iR1, iR2, . . . iRN by PsiFETs 100PjbR0, 100PjbR1, 100PjbR2, . . . 100PjbRN, respectively; while inputs S0, S1, S2, . . . SN are converted to current iS0, iS1, iS2, . . . iSN by PsiFETs 100PjbS0, 100PjbS1, 100PjbS2 . . . 100PjbSN, respectively.

A pair of CiFETs, 20jb1 and 20jb2 and a first pair of PsiFETs 100Pjb1 and 100Pjb2, and a second pair of PsiFETs 100Pjb3 and 100Pjb4 are arranged to form a latch, where gates of CiFETs 20jb1 and 20jb2 are coupled together to common mode voltage Vcm; sources 20jb1t1 and 20jb2t1 of PiFETs of CiFETs 20jb1 and 20jb2, respectively, are coupled to Vdd, and sources 20jb1t4 and 20jb2t4 of NiFETs of CiFETs 20jb1 and 20jb2, respectively, are coupled to Vss. The first pair of PsiFETs 100Pjb1 and 100Pjb2 are arranged together where the source channel gates 100Pjb1gs and 100Pjb2gs are coupled together to common mode voltage Vcm; and sources 100Pjb1s and 100Pjb2s are coupled to Vdd. Similarly, the second pair of PsiFETs 100Pjb3 and 100Pjb4 are arranged together where the source channel gates 100Pjb3gs and 100Pjb4gs are coupled together to common mode voltage Vcm; and sources 100Pjb3s and 100Pjb4s are coupled to Vdd.

iR0, iR1, iR2, . . . iRN form a reset current signal, iReset; and iS0, iS1, iS2, . . . iSN form a set current signal, iSet. The reset current signal iReset is fed to the NiPort 20jb2t6 of CiFET 20jb2 and to drain 100Pjb3d of the PsiFET 100Pjb3; while the set current signal iSet is fed to the NiPort 20jb1t6 of CiFET 20jb1 and drain 100Pjb2d of the PsiFET 100Pjb2. Drain channel gates 100Pjb3gd and 100Pjb4gd are coupled with drain 20jb1t2 of PiFET and drain 20jb1t3 of NiFET of CiFET 20jb1 to form output voltage, vQ; drain channel gates 100Pjb1gd and 100Pjb2gd are coupled with drain 20jb2t2 of PiFET and drain 20jb2t3 of NiFET of CiFET 20jb2 to form output voltage vQ_. Drain 100Pjb1d of the PsiFET 100Pjb1 provides output current iQout, while the drain 100Pjb4d of the NsiFET 100Pjb4 provides output current iQout_.

FIG. 10c shows plots that demonstrate the current-steered LATCH −170° C., −55° C., 25° C., 125° C., & 275° C. example-waveforms. The graphs in FIG. 10c refer to the circuit in FIG. 10b. The flip-flop shown in FIG. 10b was deliberately run at low power. Its operational temperature range is narrower and its operational speed is lower. The plot starting from the bottom of FIG. 10c shows the reset current pulse into the NiPort of the Q_ side of the CiFET flip flop pair. The second plot from the bottom shows a set current pulse into the NiPort of the Q side of the CiFET flip flop pair. The middle trace shows the current flowing from Vdd through the Q side of the CiFET flip-flop pair. Note that the pair of CiFET flip-flops is drawing twice that current or about 70 na total. The second trace from the top is the current logic signal output of the Q side of the flip-flop, iQout, and the top trace is the current logic signal output of the Q_ side of the flip-flop, iQout_.

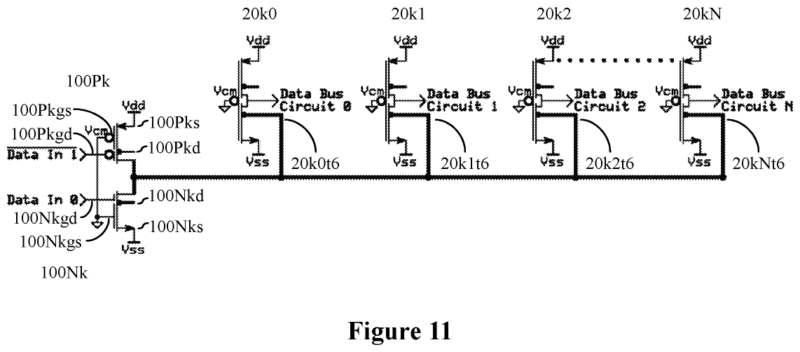

An array access system is constructed as shown in FIG. 11, which provides a bidirectional current data bus structure using CiFET/CsiFET according to the present invention. The incoming data (“0”,“1”) enters logic that splits the “0” and “1” of the data stream into two drive ports, drain channel gate 100Pkgd of PsiFET 100Pk for “1”s, Data In 1; drain channel gate 100Nkgd of NsiFET 100Nk for “0”s, Data in 0. These drain channel gates 100Pkgd and 100Nkgd in turn drive respective PiFET/PsiFET and NiFET/NsiFET, or a single iFET/siFET turning it on, causing the respective PsiFET and/or NsiFET device to either sink or source current into that data bus 1100d. The “0” logic state drives current into the common data bus 1100d. This pushed current is received by one or more data bus receivers. The data bus 1100d must have enough current to drive the input resistance of one or more receiving iPorts, here shown as NiPorts 20k0t6, 20k1t6, 20k2t6, . . . 20kNt6. In a similar fashion the “1” logic state activates an iFET/siFET or single iFET/siFET that sinks or pulls current on the common data bus 1100d.

The CiFET receiver 20k0, 20k1, 20k2, . . . , or 20kN reacts to the current being pushed or pulled from its NiPort 20k0t6, 20k1t6, 20k2t6, . . . or 20kNt6 which in turn causes the receivers 20k0, 20k1, 20k2, . . . , 20kN output common drain voltage VDB0, VDB1, VDB2, . . . VDBN to change. This voltage may be used as a logic signal or can be turned into a current logic signal as shown in FIGS. 3a to 3d and FIGS. 4a to 4d.

As the bus is current driven its voltage levels change only a little, and do not engage the data paths parasitic capacitances that hinder the phase coherency of a voltage driven data bus. In FIG. 11 only the data bus is shown, in a complete data bus system the read, write and selection control lines are also needed. These control lines may either be voltage or current logic signals. If the control lines are also current based logic signals the entire data bus and control line structure avoids the ambiguity of parasitic capacitance and its impact. By avoiding the parasitic capacitance impact the current based logic bus will run unhindered by the charging and discharging of these parasitics and will therefore run faster. Note that with the current driven bus all the parasitics are combined into a net parasitic capacitance instead of appearing somewhat separately as a distributed capacitance at each input as they do with a voltage based system. By running as a current based bus the data maintains a higher phase coherency and the temporal jitter seen at each one of the data bus taps is dramatically reduced.

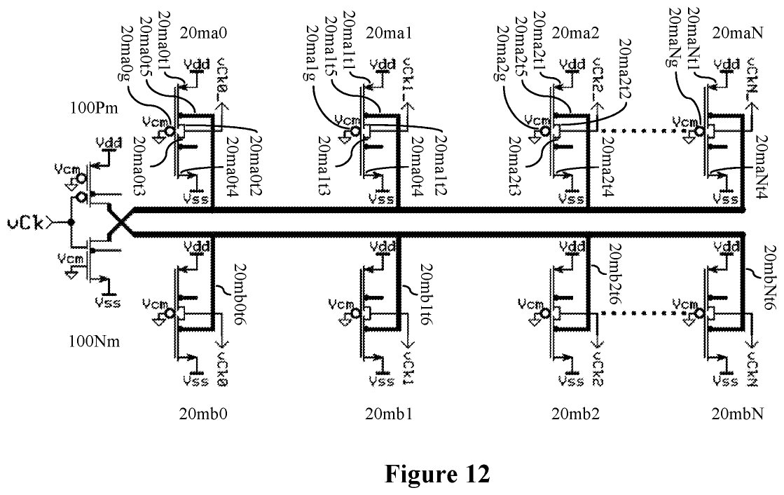

FIG. 12 shows yet another application for CiFET/CsiFET current transfer logic, which is a system that distributes a common wire logic current pulses that carry clock information. Present clocks speeds of an IC hover around 3.5 GHz; this corresponds to a wavelength of about 8.5 cm, thus propagation in an IC wire could be expected to move at 0.5 to 0.75 the speed of light, and in circuits, this is much slower still. So, with IC feature size 100's of times smaller than this to the first order the current density in IC length clock tree lengths can be considered quasi static. As such each CiFET/CsiFET clock tap that sips from this current charge transfer current tree will see closer phase coherency than loaded voltage-based clock trees.

PsiFET 100Pm converts the clock signal voltage vCk into current iOut in the same way as shown in FIG. 3c; while NsiFET 100Nm converts the clock signal voltage vCk into current iOut—in the same way as shown in FIG. 3d. The system comprises CiFETs 20ma0, 20ma1, 20ma2, 20ma3, 20ma4, 20ma5, . . . , 20maN and CiFETs 20mb0, 20mb1, 20mb2, 20mb3, 20mb4, 20mb5, . . . , 20mbN. Gates 20ma0g, 20ma1g, 20ma2g, 20ma3g, 20ma4g, 20ma5g, . . . , 20maNg, 20mb0g, 20mb1g, 20mb2g, 20mb3g, 20mb4g, 20mb5g, . . . , 20mbNg are coupled to common mode voltage Vcm; sources of PiFETs 20ma0t1, 20ma1t1, 20ma2t1, 20ma3t1, 20ma4t1, 20ma5t1, . . . , 20maNt1, 20mb0t1, 20mb1t1, 20mb2t1, 20mb3t1, 20mb4t1, 20mb5t1, . . . , 20mbNt1 are coupled to Vdd; sources of NiFETs 20ma0t4, 20ma1t4, 20ma2t4, 20ma3t4, 20ma4t4, 20ma5t4, . . . , 20maNt4, 20mb0t4, 20mb1t4, 20mb2t4, 20mb3t4, 20mb4t4, 20mb5t4, . . . , 20mbNt4 are coupled to Vss. Each CiFET's drains of PiFET and NiFET, 20ma0t2 and 20ma0t3; 20ma1t2 and 20ma1t3; 20ma2t2 and 20ma2t3; 20ma3t2 and 20ma3t3; 20ma4t2 and 20ma4t3; 20ma5t2 and 20ma5t3; . . . ; 20maNt2 and 20maNt3; 20mb0t2 and 20mb0t3; 20mb1t2 and 20mb1t3; 20mb2t2 and 20mb2t3; 20mb3t2 and 20mb3t3; 20mb4t2 and 20mb4t3; 20mb5t2 and 20mb5t3; . . . ; 20mbNt2 and 20mbNt3 are coupled together to form voltage clock signal out vCk0; vCk1; vCk2; vCk3; vCk4; vCk5; . . . , vCkN; vCk0_; vCk1_; vCk2_; vCk3_; vCk4_; vCk5_; , vCkN_; respectively.

Clock current iOut is, then, fed to NiPorts 20ma0t6, 20ma1t6, 20ma2t6, 20ma3t6, 20ma4t6, 20ma5t6, 20maNt6 of CiFETs 20ma0, 20ma1, 20ma2, 20ma3, 20ma4, 20ma5, . . . , 20maN, respectively; while clock current iOut_ is fed to PiPorts 20mb0t5, 20mb1t5, 20mb2t5, 20mb3t5, 20m54t5, 20mb5t5, 20mbNt5 of CiFETs 20mb0, 20mb1, 20mb2, 20mb3, 20mb4, 20mb5, 20mbN.

FIG. 13 illustrates a schematic diagram of a charge-based edge to pulse generator, comprising a pair of CiFET 20n1 and 20n2 having their gate 20n1gand 20n2gcoupled together to a common mode voltage Vcm; the sources 20n1t1 and 20n2t1 of PiFETs of CiFETs 20n1 and 20n2 are coupled to Vdd; the sources 20n1t4 and 20n2t4 of NiFETs of CiFET 20n1 and 20n2 are coupled to Vss. Input Vin is connected to a gate 20n3gof a third CiFET 20n3, and to the drain channel gage 100Nn1gd of the NsiFET 100Nn1 for converting to current signal iSet_. The drains 20n3t2 and 20n3t4 of PiFET and NiFET, respectively, of the CiFET 20n3 are coupled to the capacitor, C-delay, and to the drain channel gate 100Nn6gd of NsiFET 100Nn6, for converting voltage into current signal iReset_. The current signal iSet_ and iReset_ controls the latch based on CiFET 20n1 and 20n2, a first pair of NsiFETs 100Nn2 and 100Nn3, and a second pair of NsiFETs 100Nn4 and 100Nn5, where source gates 100Nn2gs and 100Nn3gs of the first pair of NsiFETs 100Nn2 and 100Nn3 are coupled together with Vcm; and source channel gates 100Nn4gs and 100Nn5gs of NsiFETs 100Nn4 and 100Nn5 are also couple together with Vcm. Drain channel gates 100Nn2gd and 100Nn3gd of the first pair of NsiFETs 100Nn2 and 100Nn3 are coupled together with drains 20n1t2 and 20n1t3 of the PiFET and NiFET of CiFET 20n1 for form Vout_; while drain channel gates 100Nn4gd and 100Nn5gd of the second pair of NsiFETs 100Nn4 and 100Nn5 are coupled together with drains 20n2t2 and 20n2t3 of the PiFET and NiFET of CiFET 20n2 for form vOut. The set current signal iSet_ is fed to PiPort 20n1t5 of CiFET 20n1 and to drain 100Nn3d of NsiFET 100Nn3; where reset current signal iRest_ is fed to PiPort 20n2t5 of the CiFET 20n2 and to drain 100Nn4d of NsiFET 100Nn4.

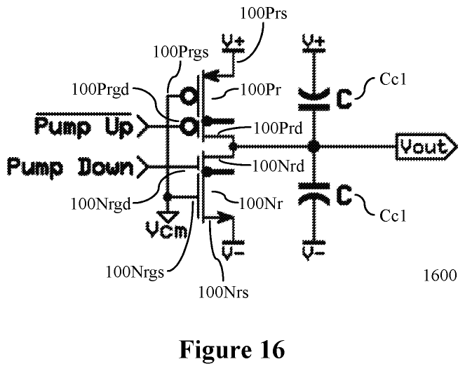

The charge-based edge to pulse generator shown in FIG. 13 is an adjustable. The generator can put out a controlled pulse of charge. This charge, pulse can be used to drive further logic systems or it could be used, to drive the accumulating capacitor that is as shown in FIG. 16. The basic structure is that of a latch with iSet_ and iRest_ current signal controls. The Vin triggering pulse enters the generator, this pulse pulls current from the PiPort 20n1t5 of the CiFET 20n1 driving its drains 20n1t2 and 20n1t3 toward Vss. This new state is communicated to the other side of the flip-flop causing the toggle action. The Vin input is also applied to the CiFET 20n3 connected to the capacitor C-delay causing it to turn on and begin to charge the capacitor C-delay. This causes the capacitor C-delay to accumulate charge and makes the capacitors voltage rise. The capacitor C-delay is charged through on resistance of that CiFET 20n3 which can be dynamically changed or changed according to design requirement(s). As soon as the capacitor C-delay charges to a sufficient level, the capacitor C-delay provides the required reset state input voltage to the flip-flop which causes the flip-flop to reset to its initial state. A discharge switch (not shown) that dumps the charge on the capacitor C-delay may be added for discharging as the flip flop is reset. Once back in the initial state, the circuit is ready to accept a new Vin pulse which starts the one shot action to occur again.

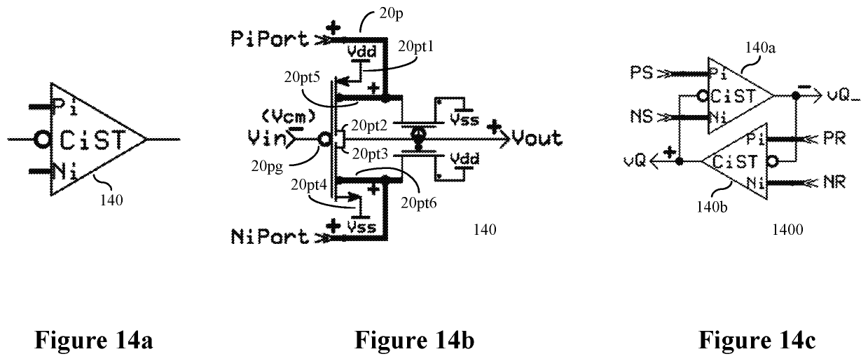

FIGS. 14a, 14b and 14c show yet further application of CiFET/CsiFET, where an exemplary implementation of Schmitt trigger using CiFETs/CsiFETs, where the Schmitt trigger with a threshold detection device whose detection level shifts between the detect and the loss of detection state. It was invented by Dr. Otto Schmitt to help in the study of depolarization response in nerves. In this embodiment of the present invention, this change in threshold is generated by the process that begins with an increase in the to be detected input voltage level. This produces a drop in the Vout voltage. As the output voltage drops the p-channel CMOS begins to turn on sinking current from the PiPort of the CiFET structure. Drawing current from the PiPort further drives the Vout voltage toward Vss. The detection process has introduced a change in the circuit that in-turn changes the value of the return to initial state threshold. The ON threshold is different from the OFF threshold that is the Schmitt trigger produced with a minimal set of parts, threshold set using the CiFETs iRatio at design time.

Referring to FIGS. 14b and 14c, the Schmitt trigger circuit 140 is enhanced from the one shown in FIG. 7b as another back to back CiFET/CsiFET Schmitt trigger (or CiST) is added as shown in FIG. 14c. CiST 140 comprises a CiFET 20p, where the gate 20pg for receiving voltage data Vin, drains 20pt3 and 20pt4 are coupled together to form Vout; PiPort 20pt5 and NiPort 20pt6 are for receiving set/reset signal. The dual Schmitt trigger 1400 is shown in FIG. 14c, where two CiST 140a and 140b are connected back to back, by connecting Vout of one of the CiST to Vin of the other. The dual Schmitt trigger 1400 where acts now as a flip-flop with both SET and RESET controls. The PS and NS of CiST 140a refer to the PiPort SET and NiPort SET input ports. Either of the NS or PS ports may be used to enter the SET logic pulse. In a similar fashion PR and NR refer to the NiPort RESET and the PiPort RESET inputs, again either port could be used to deliver the RESET pulse. Note that this flip-flop made using the hysteresis of the Schmitt trigger will have the hysteresis required to slightly offset the internal SET/RESET switch point, thus eliminating the dither that can occur with noisy Set and RESET inputs.

FIG. 15b shows four (4) latches 1000a, 1000b, 1000c and 1000d based on CiFET/CsiFET, each latch as the same structure as the latch 1000 shown in FIG. 10b, are stacked on top of each other in a parallel fashion. With a 1-volt Vdd against Vss, each of the stacked CiFET/CsiFET latches would operate on 0.250 Vdc. The common mode voltage reference for each level would be different and could be generated by a similar stacked Vcm generators using CiFETs/CsiFETs 20q0, 20q1, 20q2, 20q3 and 20q4 for generating common mode voltages Vcm0, Vcm1, Vcm2 and Vcm3, as also shown in FIG. 15a. This structure could support many parallel channels of data flow which could in turn support stacked CiFET/CsiFET logic structures that need such parallel data flow. The ability of CiFET/CsiFET to operate with Vdd's below 250 my uniquely allows such circuit stacking even when using solar cells or other battery sources. A 3D stack of logic structures presents several unique pathways for signals and structures to communicate with each other, for example a logic signal may jump 2 or three levels to another level. In a logic structure, such as FIG. 15b depicts, current logic signals from one layer may additionally enter the iPorts of either the P or N iPort of other layers with consideration to the DC bias level. This capability moves logic design from a 2D structure to a 3D structure which in turn increases the possible logic density that can be designed into a given silicon area.

FIG. 16 shows a schematic diagram of a charge pump 1600, comprising a complementary pair of PsiFET 100Pr and NsiFET 100Nr, where source 100Prs of the PsiFET 100Pr is coupled to V+; source 100Nrs of NsiFET 100Nr is coupled to V−; source channel gates 100Prgs and 100Nrgs of PsiFET 100Pr and NsiFET 100Nr are coupled together with a common mode voltage Vcm; drains 100Prd and 100Nrd of PsiFET 100Pr and NsiFET 100Nr are coupled together for form Vout; and Vout are coupled to V+ via a capacitor Cc1 and to V− via a capacitor Cc2. Drain channel gate 100Prgd is arranged to receive Pump Up signal, while drain channel gate 100Nrgd is arranged to receive Pump Down signal. The charge pump moves charge into or out of accumulating or integrating capacitors Cc1 and Cc2. The charge pump lines (Pump Up) or (Pump Down) are to be driven by one shot device where each Pump Up or Pump Down pulse delivers a fixed amount of charge to the integrating capacitors Cc1, Cc2. This increment or decrement of charge over the capacitors Cc1, Cc2 change the voltage across the capacitors Cc1, Cc2. The amount of charge delivered may be adjusted by changing the period of the driving (Pump Up or Pump Down) logic pulse. A logic activated switch (not shown) may be added, which would discharge the capacitors Cc1, Cc2 to start the charge discharge sequences from a known starting point.

The ability to control the charge per pulse in a graded fashion allows the CiFET binary logic to move from the digital world back into the analog world by depositing charge on a capacitor in a graded fashion which will change the capacitors voltage in a graded analog fashion.

Overcoming Previous Limitations
1. The ½CV² losses are minimized because the node voltage only changes locally is a change in signal current interacts with an incremental change in the connection conductivity. The local conditions produce the local node voltage {ΔVnode=ΔiPort/ΔConductivity}. These conditions are local and design considerations can ensure local conductivities are high, reducing further the drive to these parasitic distributed capacitances.
2. Noise between the sender and receiver is dramatically reduced. A noise margin measurement for a figure of merit in a current based system is {R_{IN}^{receiver}/R_{OUT}^{transmitter}. With the receiver input resistance on the order of} 50 ohms and with a low estimate for a current transmitter output resistance of one megohm the inherent signal to noise rejection is on the order of one part in 10,000. Current based steering logic is inherently faster than voltage swing based logic. However current based steering logic requires a DC bias current, so its use is targeted at the very fast applications data intensive applications like data busses. The power demands remain to the first-order constant irrespective of the speed that the logic operates.
3. CiFET current based logic easily supports extensive fan in AND, NAND, OR, NOR wired logic connections. This allows interfacing with array structures and supports scaling, should the size of the array change. The ease of the CiFETs wired or connections reduce the number logic gates required and reduce interconnect requirements.
4. CiFET/CsiFET logic while introducing current based logic can also support voltage swing based logic. Current switching logic is faster but draws more DC power. CiFET structures uniquely support both current and voltage modes in some configurations at the same time.
5. Surface area of CiFET/CsiFET logic is the same or slightly more compact than CMOS for general logic. However, the CiFET/CsiFET logic excels at structural wired OR or AND needs as arise when interfacing arrays. In these types of array wired OR or AND structures the size savings may be dramatic. CiFET/CsiFET logic structure size with process node changes.

Additional Solutions to Previous Limitations

Bus structures needing high-speed and noise immunity which would be found in the internal chips ultrafast buses. These buses could include applications like pipeline hyper threading or memory accessing were bus activity is continuous and high-speed is a paramount, these high-speed designs are limited by heating effects the CiFET/CsiFET logic leads to predictable heating under load. In order to be compatible with an already complex CMOS design infrastructure interfacing to CMOS circuitry must be seamless, CiFET/CsiFET logic provides this capability.
1. CiFET/CsiFET logic circuitry enables the passage of current signal levels or packets of charge a pulse of current. The CiFET transistor supports direct current to voltage conversion and voltage to controlled current transforms. Current pulses are used to trip several CiFET flip flop designs and provide a way to implement another form of graded logic were responses are integrated.
2. The CiFET/CsiFET device enables a new type of current steering latch illustrated in FIGS. 10a and 10b whose bias current is roughly equal to the low state current minimum. Additionally, in another form latches based on CiFET/CsiFET as shown in FIGS. 9a and 9b can hold a voltage with no bias current demand. The properties of the various forms of latches, D type, RS or JK are adjustable at fabrication time by adjusting the location of the extra channel node diffusions, this provides a wide latitude of design options for the designer where with the latches can be designed to be slow of fast directly, and if needed parameters can be adjusted dynamically inside the circuit by for example controlling the supplied Vdd to a special circuit section which will dynamically change the CiFET/CsiFET operating parameters.
3. CiFET/CsiFET logic design either binary or graded benefits by having many controllable parameters of the basic devices at their disposal. CiFET/CsiFET design brings the capability to adjust the iRatio this expresses the strength of the inner channels to the outer channels produced when the extra nodes are introduced. The iRatio is defined as iRatio=[(W/Lₒᵤₜₑᵣ)/(W/Lᵢₙₙₑᵣ)], here the strengths of the P and N channels are assumed to be the same. Wide design leeway is provided adjusting the CiFET/CsiFET strengths either in synchrony or not. Since the mobilities of the P channels and the N channels are different the P channel multiplier is a number that expresses a physical difference in device size that is needed for a balance point. Changing this P channel multiplier changes that balance point and will shift the operating parameters to the benefit of divergent designs that push the CiFET/CsiFET concept to its expanding limits.
4. CiFET/CsiFET circuits in general use a self-generated reference called the common mode voltage; the circuit to generate the common mode voltage is shown in FIG. 1a to 1c. By using this common mode voltage is a reference many noise problems associated and found on the Vdd line in the Vss line are bypassed. Every logic loads that introduce spikes on the Vdd line in the Vss line can be reflected in voltage swing levels and cause false triggering. Voltage swing logic's Vmin and Vmax voltage swings are often determined by these expected noise margins. Using current for logic levels brings a number of new inherent noise reducing characteristics into play such as the noise margin measurement mentioned earlier.
5. CiFET/CsiFET logic provides a wide temperature operating range, beyond the most rigorous mil spec of minimally plus and −50° C. The on the most stringent mil spec requirements. Details of the operating range can be found in the PCT International Application No. PCT/US2015/042696, the contents of which are incorporated herein by reference in its entirety. The CiFETs operational insensitivity to the change in the weak inversion characteristics and ultralow temperature and the weak inversion characteristic changes that occur and alter high temperature leads to the reasonable conclusion that the CiFET should work in the face of ionizing radiation to the point where the ionization path damage destroys the structures channels are nodes.
6. The CiFET/CsiFET resilience to device parameter changes that might occur during process runs means the wafers will have a higher operational yield. The CiFET/CsiFET circuit will show great operational insensitivity to Monte Carlo device aging.
7. Operational insensitivity to parameter variations means inter-circuit timing margins will remain stable and timing closure conditions can be made tighter, allowing more speed, higher yield along with more consistent designs and shorter design cycles.
8. Two types of logic are emerging discrete levels, binary CMOS being the most prevalent and a graded logic response that assigns logic true or false values on the probability of such a logic choice. The CiFET/CsiFET device can bridge between these two logic forms as it can operate in both forms a graded response which requires a certain linear fidelity and a binary form which requires a high gain, high speed invertor and a few logic structures.

1. A field effect transistor comprising:
a. a source and a drain, wherein the source and drain define a channel;
b. a diffusion that divides the channel into a source channel segment between the source and the diffusion and a drain channel segment between the drain and the diffusion;
c. a source channel gate that is coupled to the source channel segment; and
d. a drain channel gate that coupled to the drain channel segment
wherein sizes of the source channel gate and the source channel segment are different from sizes of the drain channel gate and the drain channel segment, respectively.

2. The field effect transistor as recited in claim 1, wherein the diffusion is a current input or current output node.

3. The field effect transistor as recited in claim 1, wherein the diffusion is a current sink or current source node.

5. The field effect transistor as recited in claim 1, wherein the source channel gate is coupled to a common mode voltage, the source is coupled to a power source, and the drain channel gate is configured to receive a logic voltage input for providing a logic current output at the drain.

6. A solid-state device, comprising:
a. a complementary pair of first and second field effect transistors as recited in claim 1, wherein, the drain of the first complementary field effect transistor and the drain of the second complementary field effect transistor are coupled together to form a drain port.

7. The solid-state device as recited in claim 6, wherein the source channel gate and the drain channel gate of the first complementary field effect transistor and the source channel gate and the drain channel gate of the second complementary field effect transistor are coupled together to a common mode voltage; and
wherein the solid-state device is arranged to receive a logic current input at the diffusion of the first complementary field effect transistor and/or the second diffusion of the second complementary field effect transistor to generate a logic voltage output at the drain port.

8. A logic current to logic voltage converter, comprising:
a. a complementary pair of first and second field effect transistors, each comprising a source and a drain, wherein the source and drain of the first transistor define a first channel and the source and drain of the second transistor define a second channel;
b. a first diffusion (first iPort) that divides the first channel into a first source channel segment between the source and the first iPort, and a first drain channel segment between the drain and the first iPort;
c. a second diffusion (second iPort) that divides the second channel into a second source channel segment between the source and the second iPort and a second drain channel segment between the second iPort and the drain;
d. a gate coupled to the first source channel segment, the first drain channel segment, the second source channel segment, and the second drain channel segment; and
wherein the drain of the first complementary field effect transistor and the drain of the second complementary field effect transistor are coupled together to form a drain port;
wherein the gate is coupled to a common mode voltage, the sources of the first and second complementary field effect transistors are coupled to power supply; and
wherein the logic current to logic voltage converter is arranged to receive a logic current input at the first iPort or the second iPort for generating a logic voltage output at the drain port.

9. A charge transfer logic module having two or more logic input and a logic output, comprising:
a. a solid-state device as recited in claim 3, wherein the sources of the first and second complementary field effect transistors are coupled to a power supply;
b. for each of two or more logic input voltage, a logic voltage to logic current converter for converting said each logic input voltage into a logic current;
wherein the diffusion of the first or the second complementary field effect transistor is configured to receive said logic current from the converter; and
wherein the drain port of the solid-state device is configured to output the logic voltage output.

10. The charge transfer logic module as recited in claim 9, wherein the logic voltage to logic current converter comprises a field effect transistor, comprising:
a. a source and a drain, wherein the source and drain defines a channel;
b. a diffusion that divides the channel into a source channel segment between the source and the diffusion and a drain channel segment between the drain and the diffusion;
c. a source channel gate that is coupled to the source channel segment; and
d. a drain channel gate that coupled to the drain channel segment;
wherein the source is coupled with a power supply, the source channel gate is coupled with a common mode voltage, the drain channel gate is configured to receive one of the two or more logic voltage input for generating a logic current output from the drain.

11. A logic voltage to logic current converter, comprising:
a. a field effect transistor, comprising:
i. a source and a drain, wherein the source and drain defines a channel;
ii. a diffusion that divides the channel into a source channel segment between the source and the diffusion and a drain channel segment between the drain and the diffusion;
iii. a source channel gate that is coupled to the source channel segment; and
iv. a drain channel gate that coupled to the drain channel segment;
wherein the source is coupled with a power supply, the source channel gate is coupled with a common mode voltage, the drain channel gate is configured to receive a logic voltage input for generating a logic current output from the drain.

12. A data bus structure, comprising:
a. a bus;
b. a bus transmitter comprising a field effect transistor, comprising:
i. a source and a drain, wherein the source and drain defines a channel;
ii. a diffusion that divides the channel into a source channel segment between the source and the diffusion and a drain channel segment between the drain and the diffusion;
iii. a source channel gate that is coupled to the source channel segment; and
iv. a drain channel gate that coupled to the drain channel segment;
wherein the source is coupled with a power supply, the source channel gate is coupled with a common mode voltage, the drain channel gate is configured to receive a logic voltage input for generating a logic current output from the drain to the bus; and
c. a bus receiver comprising a complementary pair of first and second field effect transistors, each comprising:
i. a source and a drain, wherein the source and drain of the first transistor define a first channel and the source and drain of the second transistor define a second channel;
ii. a first diffusion (first iPort) that divides the first channel into a first source channel segment between the source and the first iPort, and a first drain channel segment between the drain and the first iPort;
iii. a second diffusion (second iPort) that divides the second channel into a second source channel segment between the source and the second iPort and a second drain channel segment between the second iPort and the drain;
iv. a gate coupled to the first source channel segment, the first drain channel segment, the second source channel segment, and the second drain channel segment; and
wherein the drain of the first complementary field effect transistor and the drain of the second complementary field effect transistor are coupled together to form a drain port;
wherein the gate is coupled to a common mode voltage, the sources of the first and second complementary field effect transistors are coupled to power supply; and
wherein the bus receiver is arranged to receive the logic current from the bus at the first iPort or the second iPort for generating a logic voltage output at the drain port.

13. A charge-based clock-tree, comprising:
a. a bus structure as recited in claim 122;
wherein the drain channel gate of the bus transmitter is configured to receive a logic voltage clock signal for conversion into a logic current clock signal to be transmitted on the bus.
